(19) United States
(12) Patent Application Publication
(10) Pub. No.: US 2013/0180452 A1
(43) Pub. Date: Jul. 18, 2013

(54) FILM DEPOSITION APPARATUS

(71) Applicant: Tokyo Electron Limited, Tokyo (JP)

(72) Inventors: Hitoshi KATO, Iwate (JP); Toshiyuki Nakatsubo, Iwate (JP); Shigehiro Miura, Iwate (JP)

(73) Assignee: Tokyo Electron Limited, Tokyo (JP)

(21) Appl. No.: 13/742,697

(22) Filed: Jan. 16, 2013

(30) Foreign Application Priority Data
Jan. 18, 2012 (JP) 2012-008047

(51) Int. Cl. C23C 16/458

(52) U.S. Cl. CPC C23C 16/458
USPC 118/719

(57) ABSTRACT

A film deposition apparatus deposits a thin film on a substrate by repeating a cycle of supplying plural kinds of process gases that react with each other in a vacuum chamber. The film deposition apparatus includes a turntable to hold a substrate thereon and to rotate the substrate, and a plurality of process gas supplying parts. At least one of the process gas supplying parts extends from the center to the periphery and is formed as a gas nozzle including gas discharge holes.

The gas discharge holes are formed along a length direction of the gas nozzle. The film deposition apparatus also includes current plates provided on upstream and downstream sides in a rotational direction of the turntable and extending along the length direction of the gas nozzle, and having at least one bent section bent downward from an outer edge of the current plates.

### CROSS-REFERENCE TO RELATED APPLICATIONS

This patent application is based upon and claims the benefit of priority of Japanese Patent Application No. 2012-8047, filed on Jan. 18, 2012, the entire contents of which are incorporated herein by reference.

### BACKGROUND OF THE INVENTION

1. Field of the Invention

The present invention relates to a film deposition apparatus that deposits a reaction product and forms a thin film on a substrate in a layer-by layer manner by supplying process gases that react with each other in sequence onto the substrate.

2. Description of the Related Art

An ALD (Atomic Layer Deposition) method is known that supplies plural kinds of process gases that react with each other (i.e., reactive gases) in sequence on a surface of a wafer and deposits a reaction product in a layer-by-layer manner on the surface of the wafer, as one of numerous methods that deposit a thin film such as a silicon oxide film (SiO₂) on a substrate such as a semiconductor wafer (hereinafter called a “wafer”). As disclosed in Patent Document 1, as an example of such an apparatus that deposits a film by the ALD method, there is an apparatus configured to include a turntable on which plural wafers are arranged in a circumferential direction provided in a vacuum chamber, and plural gas supplying nozzles provided facing the turntable. In this apparatus, by rotating the turntable so as to make the wafers pass through plural process areas to which the process gases are respectively supplied in sequence, adsorption processes of a silicon containing gas onto the wafer and oxidation processes of the gas adsorbed on the wafer are alternately repeated many times. Separating areas to which nitrogen gases are supplied are provided between the process areas to prevent the process gases from being mixed with each other.

Here, to perform a film deposition process at a deposition rate that meets an actual productivity level, or to cause the respective process gases to contact the respective wafers uniformly throughout the surface, the process gases have to be supplied excessively to the wafers in the respective process areas. In other words, theoretically, it is only necessary to set a flow rate of the process gases to such an extent that saturation reaction with the surface of the wafer occurs (i.e., adsorption and oxidation) because only a tiny amount of process gases is adsorbed on the wafer at one time (e.g., an amount of one layer of an atomic layer or a molecular layer), and therefore a film thickness oxidized in the oxidation process is very small. However, in fact, contact probability between the process gases and the wafers is not so high in the process areas because an atmosphere in the vacuum chamber is a vacuum atmosphere, and nitrogen gases flow around to the process areas from the separating areas. Moreover, because the turntable rotates, a period when the wafers pass the respective process areas is quite short. Due to this, as stated above, the flow rate of the process gases is set to be more than necessary.

Accordingly, for example, since the above-mentioned silicon containing gas is very expensive, running cost of the apparatus is increased. On the other hand, if the flow rate of the process gases is attempted to be decreased, a deposition rate as setting cannot be obtained, or the deposition process onto the wafer may vary within the surface of the wafer according to the locations.

Patent Document 2 discloses a technology that provides a nozzle cover for a reaction gas nozzle, but still requires an excessive amount of process gas to obtain an appropriate deposition rate, as noted from working examples described below.

[Patent Document 1] Japanese Laid-open Patent Publication No. 2010-239102

[Patent Document 2] Japanese Laid-open Patent Publication No. 2011-100956

### SUMMARY OF THE INVENTION

Embodiments of the present invention provide a novel and useful film deposition apparatus solving one or more of the problems discussed above.

More specifically, embodiments of the present invention provide a film deposition apparatus that can perform a film deposition process at a sufficient deposition rate, reducing a flow rate of process gases, in depositing a reaction product on a surface of a substrate in a layer-by-layer manner by supplying the process gases that react with each other in sequence.

According to one embodiment of the present invention, there is a film deposition apparatus configured to deposit a thin film on a substrate by repeating a cycle of supplying plural kinds of process gases that react with each other in sequence in a vacuum chamber. The film deposition apparatus includes a turntable including a substrate loading area in an upper surface to hold a substrate thereon. The turntable is configured to make the substrate loading area rotate in the vacuum chamber. The film deposition apparatus also includes a plurality of process gas supplying parts configured to supply process gases different from each other to process areas spaced apart from each other in the circumferential direction of the turntable, at least one of the process gas supplying parts extending from a central part to a periphery and being configured to be a gas nozzle including gas discharge holes to discharge the process gas toward the turntable. The gas discharge holes are formed along a length direction of the gas nozzle. The film deposition apparatus further includes a plurality of separation gas supplying parts formed between the process areas. The separation gas supplying parts are configured to supply a separation gas for separating atmospheres of the respective process areas. The film deposition apparatus also includes at least one evacuation opening configured to evacuate an atmosphere in the vacuum chamber, current plates provided on upstream and downstream sides in a rotational direction of the turntable and extending along the length direction of the gas nozzle, a circulating space above the gas nozzle and the current plates to allow the separation gas to circulate therein, and at least one bent section bent downward from an outer edge of the current plates on the outer edge side of the turntable so as to face an outer edge surface of the turntable with a gap therefrom.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view showing an example of a film deposition apparatus of an embodiment of the present invention;

FIG. 2 is a horizontal cross-sectional view of the film deposition apparatus of the embodiment;

FIGS. 3A and 3B are enlarged perspective views showing a part of the film deposition apparatus of the embodiment;

FIG. 4 is an enlarged perspective view showing apart of the film deposition apparatus of the embodiment;

FIG. 5 is a vertical cross-sectional view showing a part of the inside of the film deposition apparatus of the embodiment;

FIG. 6 is a vertical cross-sectional view showing a part of the inside of the film deposition apparatus of the embodiment;

FIG. 7 is a perspective view showing a part of the inside of the film deposition apparatus of the embodiment;

FIG. 8 is a vertical cross-sectional view showing a part of the inside of the film deposition apparatus of the embodiment;

FIG. 9 is a plan view showing a part of the inside of the film deposition apparatus of the embodiment;

FIG. 10 is an explanatory diagram to explain a nozzle cover of the film deposition apparatus of the embodiment;

FIGS. 11A and 11B are vertical cross-sectional views spreading out the film deposition apparatus of the embodiment in a circumferential direction;

FIG. 12 is a vertical cross-sectional view showing a part of the film deposition apparatus of the embodiment;

FIG. 13 is an enlarged vertical cross-sectional view showing a part of the film deposition apparatus of the embodiment;

FIG. 14 is a schematic diagram showing a way of depositing a thin film on a substrate by the film deposition apparatus of the embodiment;

FIG. 15 is a perspective view showing another example of a film deposition apparatus of an embodiment;

FIG. 16 is a perspective view showing another example of a film deposition apparatus of an embodiment;

FIG. 17 is a vertical cross-sectional view showing another example of a film deposition apparatus of an embodiment;

FIG. 18 is a vertical cross-sectional view showing another example of a film deposition apparatus of an embodiment;

FIG. 19 is a perspective view showing another example of a film deposition apparatus of an embodiment;

FIG. 20 is a perspective view showing another example of a film deposition apparatus of an embodiment;

FIG. 21 is a perspective view showing another example of a film deposition apparatus of an embodiment;

FIG. 22 is a perspective view showing another example of a film deposition apparatus of an embodiment;

FIG. 23 is a perspective view showing another example of a film deposition apparatus of an embodiment;

FIG. 24 is a horizontal cross-sectional view showing another example of a film deposition apparatus of an embodiment;

FIG. 25 is a vertical cross-sectional view showing another example of a film deposition apparatus of an embodiment;

FIG. 26 is a characteristic diagram showing a working example of a film deposition apparatus of an embodiment;

FIG. 27 is a characteristic diagram showing a working example of a film deposition apparatus of an embodiment;

FIGS. 28A through 28C are characteristic diagrams showing a working example of a film deposition apparatus of an embodiment;

FIG. 29 is a characteristic diagram showing a working example of the film deposition apparatus of an embodiment;

FIGS. 30A through 30C are characteristic diagrams showing a working example of a film deposition apparatus of an embodiment;

FIGS. 31A through 31C are characteristic diagrams showing a working example of a film deposition apparatus of an embodiment;

FIG. 32 is a characteristic diagram showing a working example of a film deposition apparatus of an embodiment;

FIGS. 33A through 33D are characteristic diagrams showing a working example of a film deposition apparatus of an embodiment;

FIGS. 34A and 34B are characteristic diagrams showing a working example of a film deposition apparatus of an embodiment;

FIGS. 35A and 35B are characteristic diagrams showing a working example of a film deposition apparatus of an embodiment;

FIG. 36 is a characteristic diagram showing a working example of a film deposition apparatus of an embodiment;

FIG. 37 is a characteristic diagram showing a working example of a film deposition apparatus of an embodiment;

FIG. 38 is a characteristic diagram showing a working example of a film deposition apparatus of an embodiment; and

FIG. 39 is a characteristic diagram showing a working example of a film deposition apparatus of an embodiment.

### DETAILED DESCRIPTION OF THE PREFERRED EMBODIMENTS

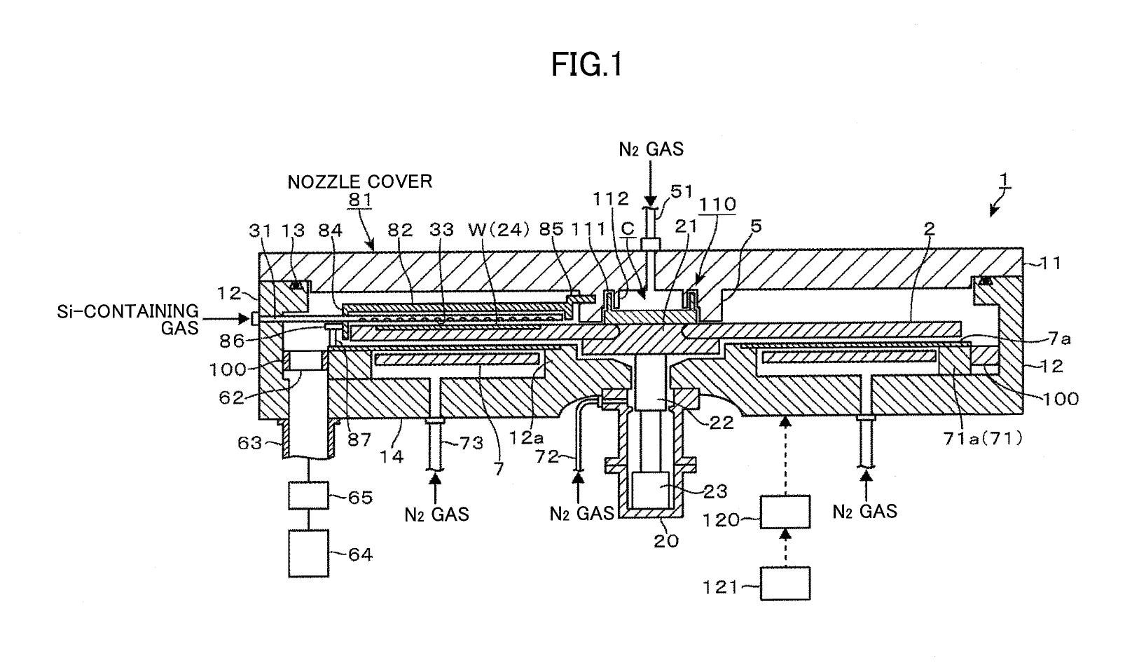

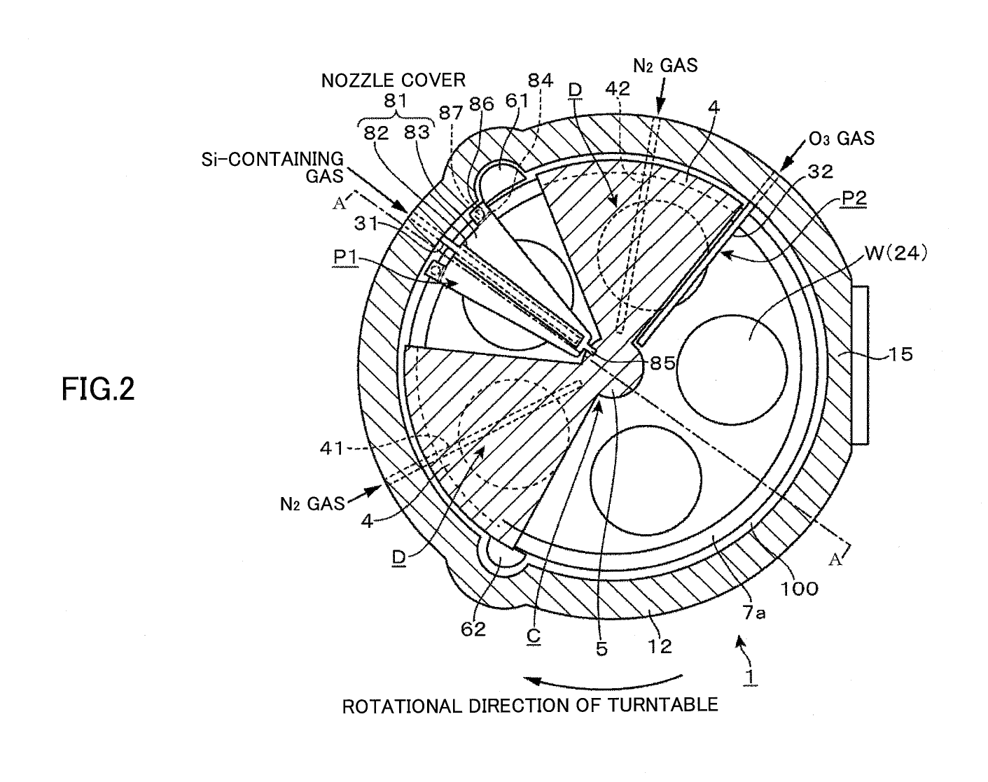

A description is given below, with reference to drawings of embodiments of the present invention. More specifically, a description is given about an example of a film deposition apparatus of an embodiment of the present invention, with reference to FIGS. 1 through 13. As shown in FIGS. 1 and 2, the film deposition apparatus includes a vacuum chamber 1 whose planar shape is an approximately round shape, and a turntable 2 provided in the vacuum chamber 1 and having the rotation center that coincides with the center of the vacuum chamber 1. First, to explain briefly about an outline of this film deposition apparatus, the film deposition apparatus deposits a thin film by using an ALD method, specifically by alternately supplying plural kinds of process gases (i.e., reactive gases) that react with each other onto a wafer W rotated by the turntable 2. As described in detail below, this film deposition apparatus is configured to be able to obtain a favorable (i.e., high) deposition rate and a thin film with a uniform thickness throughout the surface of the wafer W, while minimizing supply of the process gases onto the wafer W. Next, a description is given about respective parts of the film deposition apparatus.

The vacuum chamber 1 includes a ceiling plate 11 and a chamber body 12, and is configured to allow the ceiling plate 11 to be attachable to or detachable from for supplying an N₂ (nitrogen) gas as a separation gas is connected to the center portion on the top surface of the ceiling plate 11 in order to suppress mixture of different process gases with each other in a center area C in the vacuum chamber 1. In FIG. 1, a seal member 13 is provided in a ring form in an outer edge in the top surface of the chamber body 12, and for example, an O-ring may be used for the seal member 13.

The turntable 2 is fixed to a core part 21 having an approximately cylindrical shape at the center portion, connected to the bottom surface of the core part 21 and is configured to be rotatable around a vertical axis by a rotational shaft 22 that extends in a vertical direction. In this example, the turntable 2 rotates in a clockwise direction. FIG. 1 shows a drive part 23 that rotates the rotational shaft 22 around the vertical axis, and a case body 20 that houses the rotational shaft 22 and the drive part 23. A flange part on the upper surface side of this case body 20 is hermetically attached to the lower surface of a bottom part 14 of the vacuum chamber 1. Furthermore, a purge gas supplying pipe 72 for supplying an N₂ gas as a purge gas to an area below the turntable 2 is connected to the case body 20. The outer circumference side of the core part 21 in the bottom part 14 of the vacuum chamber 1 is formed into a ring shape so as to come close to the turntable 2 from the lower side and forms as a protrusion portion 12a.

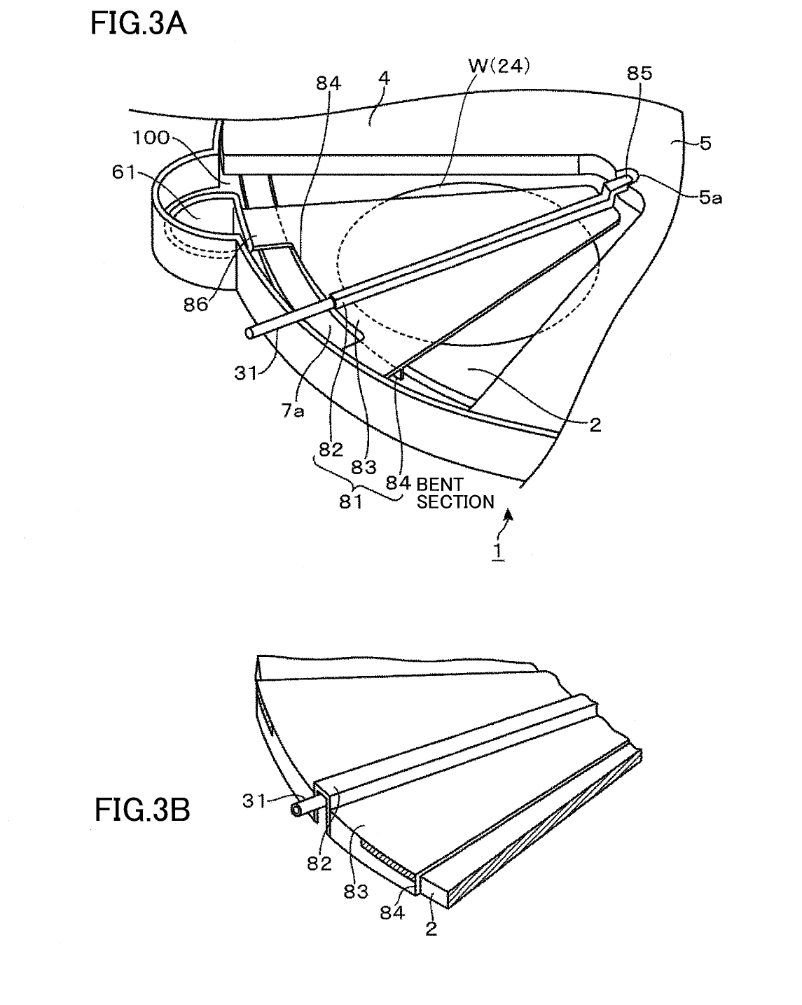

As shown in FIGS. 2 and 3A, plural circular shaped concave portions 24 to hold wafers W, for example, 300 mm in diameters thereon, are provided at plural places, for example, five places, along a rotational direction (i.e., a circumferential direction) as substrate loading areas in the surface of the turntable 2. Dimensions in diameter and depth of the concave portions 24 are set so that the surface of the wafer W and the surface of the turntable 2 (i.e., a region where the wafer W is not loaded) are even or flat when the wafer W is dropped down (held) into the concave portion 24. In the bottom surface of the concave portion 24, three through holes are formed (which are not shown in the drawings) through which pass, for example, corresponding lift pins described below to move the wafer W up and down by pushing up the wafer W from the lower side.

As shown in FIG. 2, at positions opposite to areas where the concave portions 24 in the turntable 2 pass through by the rotation, four nozzles 31, 32, 41 and 42 respectively made of, for example, quartz are arranged in a radial fashion, at intervals with each other in a circumferential direction of the vacuum chamber 1. These nozzles 31, 32, 41 and 42 are, for example, respectively installed so as to extend horizontally toward the center area C from an outer peripheral wall of the vacuum chamber 1, facing the wafer W. In this example, a separation gas nozzle 41, a first process gas nozzle 31, a separation gas nozzle 42, and a second process nozzle 32 are arranged in this order in a clockwise fashion (i.e., in a rotational direction of the turntable 2) when seen from a transfer opening 15 described below. When seen from a planar perspective, a distance e (see FIG. 7) between the tips of these respective nozzles 31, 32, 41 and 42 and the ends of the wafers W on the rotational center side in the turntable 2 is, for example, 37 mm. In addition, a distance between the lower end surfaces of the nozzles 31, 32, 41 and 42 and the wafers W on the turntable 2 is, for example, in a range from 0.5 to 3 mm (2 mm in this example). In FIG. 2, a position of the process gas nozzle 31 is shown schematically.

The respective nozzles 32, 41 and 42 except for the first process gas nozzle 31 among these nozzles 31, 32, 41 and 42 are respectively formed so as to become a cylindrical shape from the base end side (i.e., the inner wall side of the vacuum chamber 1) to the tip side (i.e., the center side of the turntable 2).

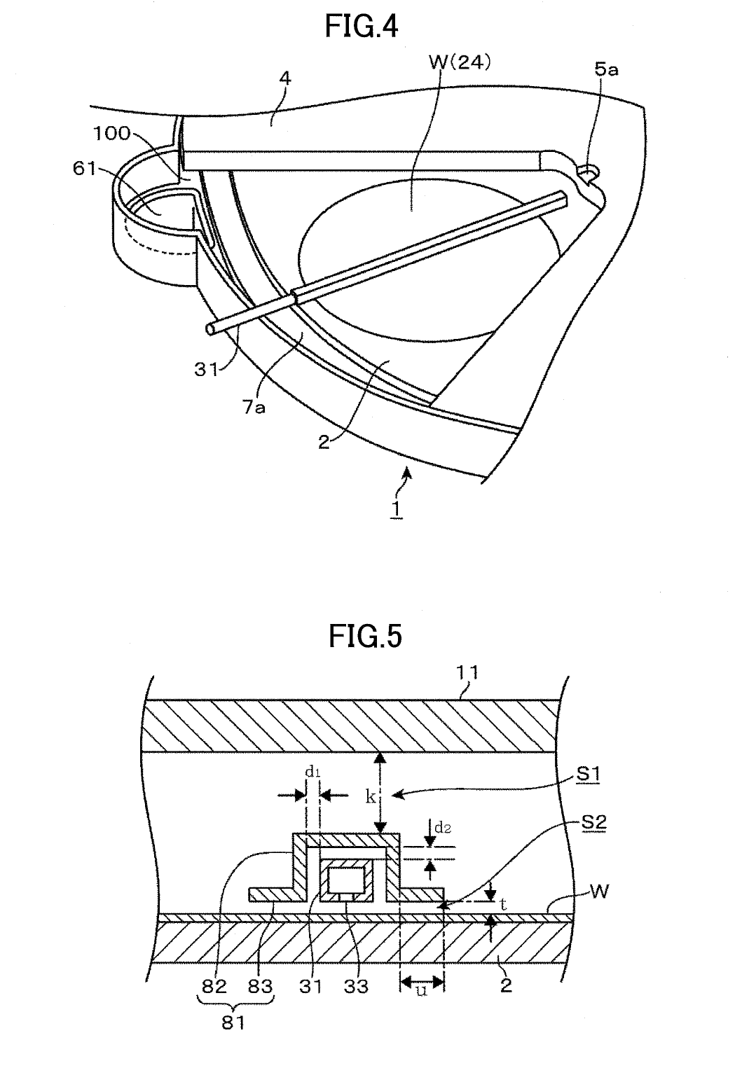

FIG. 4 is an enlarged view of the first process gas nozzle 31. As shown in FIG. 4, the first process gas nozzle 31 has a cylindrical shape from the base end side to the outer edge portion of the turntable 2, but has a rectangular-tube shape from the outer edge portion to the tip side. Moreover, the first process gas nozzle 31 is arranged so that the lower end surface of the first process gas nozzle 31 and the surface of the wafers W on the turntable 2 are parallel in the rotational direction of the turntable 2. Reasons why the first process gas nozzle 31 is formed in this manner is described in detail below. The first process gas nozzle 31 and the second process gas nozzle 32 respectively form process gas supplying parts, and the separation gas nozzles 41, 42 respectively form separation gas supplying parts. Here, FIG. 1 shows a vertical cross-sectional view cut along A-A line in FIG. 2.

The nozzles 31, 32, 41 and 42 are respectively connected to the following gas supplying sources (which are not shown in the drawing) through flow control valves. More specifically, the first process gas nozzle 31 is connected to a source of a first process gas containing Si (silicon) such as a BTBAS (bis(tertiary-butylaminosilane)):SiH₂ (NH—C(CH₃)₂) gas. The second process gas nozzle 32 is connected to a supplying source of a second process gas of an oxidation gas such as a mixed gas of an ozone (O₃) gas and an oxygen (O₂) gas. The separation gas nozzles 41, 42 are respectively connected to a supplying source of a nitrogen (N₂) gas of a separation gas. Hereinafter, a description is given by assuming that the second process gas is an ozone gas for convenience of explanation.

In the lower surfaces of the gas nozzles 31, 32, 41 and 42, gas discharge holes 33, whose opening size is, for example, 5 mm, are respectively formed along a radial direction of the turntable 2 at plural points. With regard to the respective nozzles 32, 41 and 42 except for the first process gas nozzle 31, the gas discharge holes 33 are formed at an equal distance along the radial direction of the turntable 2.

FIG. 9 is a view showing an arrangement of the gas nozzles 33 of the first process gas nozzle 31. As shown in FIG. 9, the gas discharge holes 33 are arranged in such a way that when an inner part of the outer edge portion of the turntable 2 in the first process gas nozzle 31 is equally divided into three sections in a longitudinal direction, the number of the gas discharge holes 33 (i.e., opening area) on the center area C side among the three sections is about from one and a half to three times as much as the other two sections. Accordingly, as described below, the first process gas nozzle 31 is set to discharge the process gas more on the center side than on the outer edge side of the turntable 2. Here in FIG. 9, an appearance of the first process gas nozzle 31 when seen from the lower side (i.e., wafer W side) is shown, and distribution of the gas discharge holes 33 is drawn schematically.

As shown in FIG. 2, an area under the process gas nozzle 31 is a first process area P1 to adsorb the Si-containing gas onto the wafer W, and an area under the second process gas nozzle 32 is a second process area P2 to cause the Si-containing gas adsorbed on the wafer W to react with the ozone gas. The separation gas nozzles 41, 42 are to form separating areas D that separate the first process area P1 from the second process area P2, respectively.

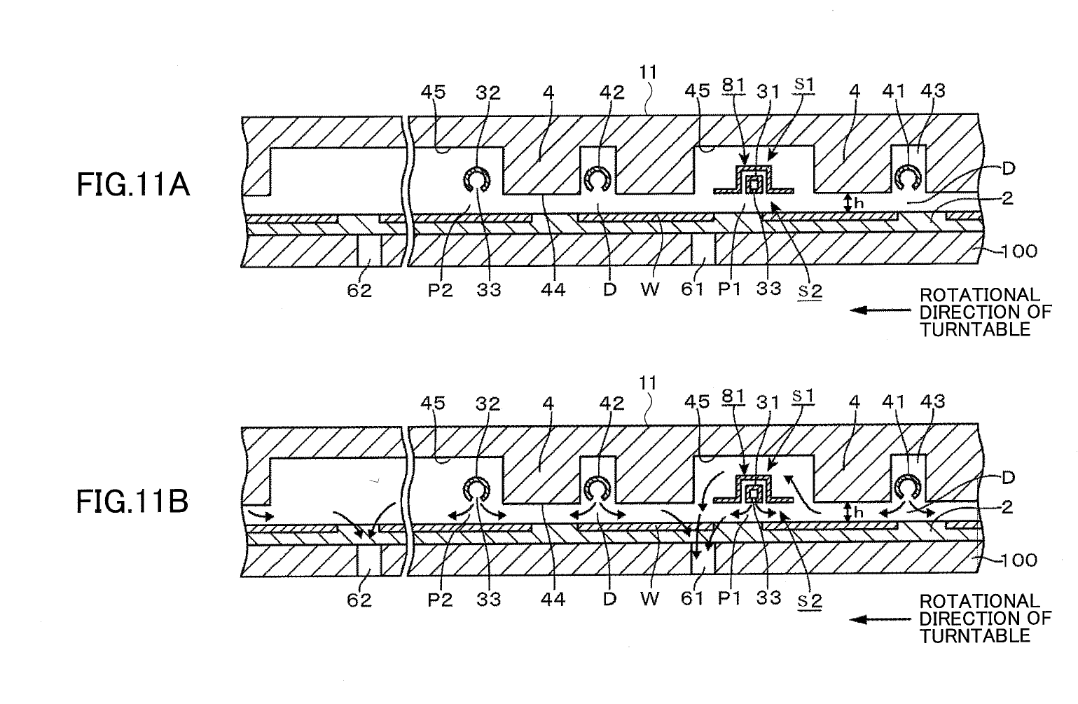

FIGS. 11A and 11B are views showing a cross-sectional configuration of the ceiling plate 11 including the separation area D. As shown in FIG. 2, the ceiling plate 11 of the vacuum chamber 1 in the separation area D includes convex portions 4 of an approximate sector, and as shown in FIGS. 11A and 11B, the separation gas nozzles 41, 42 are housed in groove portions 43 formed in the convex portions 4. Accordingly, as shown in FIG. 11A and 11B, on both sides of the separation gas nozzles 41, 42 in the circumferential direction of the turntable 2, lower ceiling surfaces (i.e., first ceiling surfaces) 44 of the lower surfaces of the convex portions 4 are arranged to prevent the respective process gases from being mixed with each other, and on both sides of the ceiling surfaces 44, ceiling surfaces (i.e., second ceiling surfaces) 45 higher than the ceiling surfaces 44 are arranged.

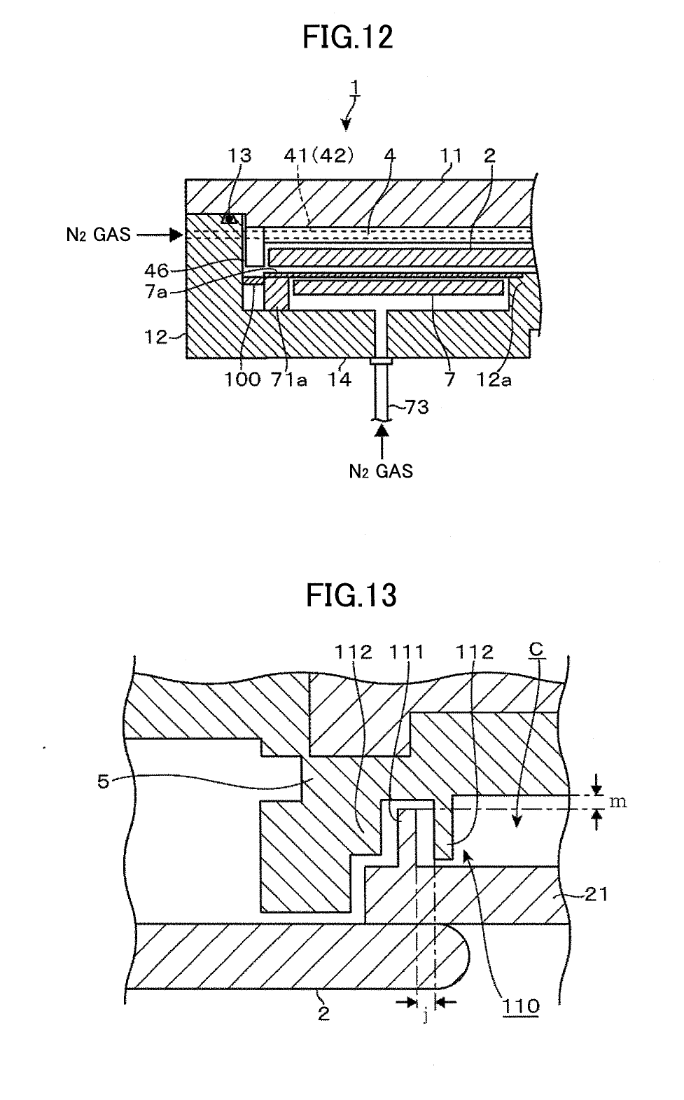

As shown in FIG. 12, the outer edge portion of this convex portion 4 (i.e., a region between the outer edge portion of the turntable 2 and the inner wall surface of the vacuum chamber 1), is bent into a L letter and forms a bent portion 46 so that the bent portion 46 faces the outer edge surface of the turntable 2 and is slightly distanced from the chamber body 12 in order to prevent the respective process gases from being mixed with each other through the outer edge surface side of the turntable 2. A distance dimension h between the lower ceiling surface 44 and the wafer W on the turntable 2 is the same degree of dimension as a distance between the bent portion 46 and the outer edge surface of the turntable 2, and is set in a range from 0.5 mm to 10 mm, and 2 mm in this example. Here, FIGS. 11A and 11B are vertical cross section of the vacuum chamber 1 cut along the rotational direction of the turntable 2 and spread out, and the dimensions of respective portions are schematically shown.

As shown in FIGS. 1 though 3, a nozzle cover (fin) 81 that is made of, for example, quartz, and formed so as to cover the first process gas nozzle 31 along the length direction is provided over the first process gas nozzle 31. This nozzle cover 81 includes an approximately boxy cover body 82 whose lower surface is open in order to house the first process gas nozzle 31, and plate-like current plates 83 that are connected to open end edges of the lower surface side of the cover body 82 on the upstream and downstream sides in the rotational direction of the turntable 2, respectively. Here, FIGS. 3A and 3B show a state of the nozzle cover 81 attached to the first process gas nozzle 31, and FIG. 4 shows a state where nozzle cover 81 is detached, respectively. Moreover, in FIG. 3B, depiction of horizontal surface parts 86 described below is omitted.

As shown in FIG. 5, the cover body 82 is configured so that the inner wall surface thereof is modeled on the outer wall surface of the process gas nozzle 31 and gap dimensions d1, d2 between the inner wall surface and the outer wall surface are the same degree as the above-mentioned distance dimension t. Hence, the process gas discharged from the first process gas nozzle 31 finds it difficult to flow into the gap between the first process gas nozzle 31 and the cover body 82. The gap dimension d1 is a distance between the first process gas nozzle 31 and the cover body 82 in the rotational direction of the turntable 2, and the gap dimension d2 is a distance between the first process gas nozzle 31 and the cover body 82 in a height direction.

A circulating space S1 is formed above the cover body 82 to allow the separation gas supplied from the separation gas nozzle 42 to circulate, flowing away from the area under the first process gas nozzle 31. The height dimension of the circulating space S1 (i.e., a dimension between the lower surface of the ceiling plate 11 and the upper surface of the cover body 82) k is, for example, from 5 to 15 mm. Here, FIG. 5 shows a vertical cross-sectional view of the cover body 82 and the first process gas nozzle 31 cut along the circumferential direction of the turntable 2.

As shown in FIG. 3B, the side surface of the cover body 82 on the outer edge side of the turntable 2 is open to let the first process gas nozzle 31 enter.

On the other hand, as shown in FIG. 7, the side surface of the cover body 82 on the rotational center side of the turntable 2 is arranged to face the tip portion of the first process gas nozzle 31 in order to prevent the separation gas supplied from the separation gas supplying pipe 51 to the center area C from flowing into an area under the first process gas nozzle 31. A distance dimension between the lower end surface of the cover body 82 on the rotational center side of the turntable 2 and the wafer W on the turntable 2 is set at the same degree as the distance dimension t. In FIG. 7, an arrangement layout about the gas discharge holes 33 of the first process gas nozzle 31 is schematically shown.

The respective current plates 83 are to suppress the separation gas from entering the lower side of the current plates 83 and to cause the process gas discharged from the first process gas nozzle 31 to circulate along the wafer W on the turntable 2. As shown in FIGS. 3A and 3B, the current plates 83 respectively extend horizontally along the surface of the turntable 2, and are formed across the length direction of the first gas nozzle 31. Furthermore, the current plates 83 are respectively formed to expand the width thereof from the center side toward the outer edge side of the turntable 2 and to become an approximate sector when seen from a planar perspective.

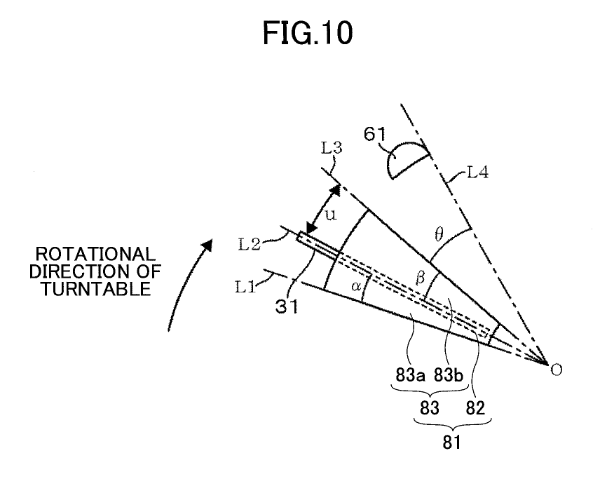

Here, as shown in FIG. 10, if the current plate 83 on the upstream side is made a current plate 83a; the current plate 83 on the downstream side is made a current plate 83b; and “first” and “second” are respectively attached to the current plates 83a, 83b of the two current plates 83, an angle α formed by a straight line L1 assing through the end on the upstream side of the first current plate 83a so as to be along the radial direction of the turntable 2 when seen from a planar perspective and a straight line L2 passing through the center of the first process gas nozzle 31 along the length direction is, for example, 15 degrees. In addition, an angle β formed by a straight line L3 passing through the end on the downstream side of the second current plate 83b so as to be along the radial direction of the turntable 2 when seen from the planar perspective and the straight line L2 is, for example, 22.5 degrees. Accordingly, for example, length dimensions u of arcs on the upper side of the outer edge portion of the turntable 2 in the first current plate 83a and the second current plate 83b are respectively 120 mm and 180 mm.

Moreover, the second current plate 83b is configured not to inhibit a flow of the process gas going from the first process gas nozzle 31 toward the evacuation opening 61 described below. In other words, the second current plate 83b is arranged not to go beyond a point on the downstream side in the rotational direction of the turntable 2 in the rim of the evacuation opening 61 and a straight line L4 passing the rotation center of the turntable toward the downstream side. More specifically, an angle θ formed by the straight line L3 and the straight line L4 is 0 degree or more, for example, 7.5 degrees. In other words, it can be said that the first process gas nozzle 31 is formed at a position that does not block the process gas flow from going toward the evacuation opening 61 even if the current plates 83a, 83b are respectively disposed on the upstream side and on the downstream side in the rotational direction of the turntable 2. Here, FIG. 10 shows the nozzle cover 81 and the turntable 2 schematically, and depicts the rotation center of the turntable 2 as an “◯”.

With respect to these current plates 83, a dimension between the lower surfaces of the current plates 83 and the surface of the wafer W on the turntable 2 is the same degree as the distance dimension t. Hence, as shown in FIG. 5, when the upstream and downstream sides in the rotational direction of the turntable 2 are seen from the discharge holes 33 of the first process gas nozzle 31, a space S2 to cause the process gas to flow along the turntable 2 is broadly formed along the rotational direction of the turntable 2 by the lower end surface of the first process gas nozzle 31 and the current plates 83.

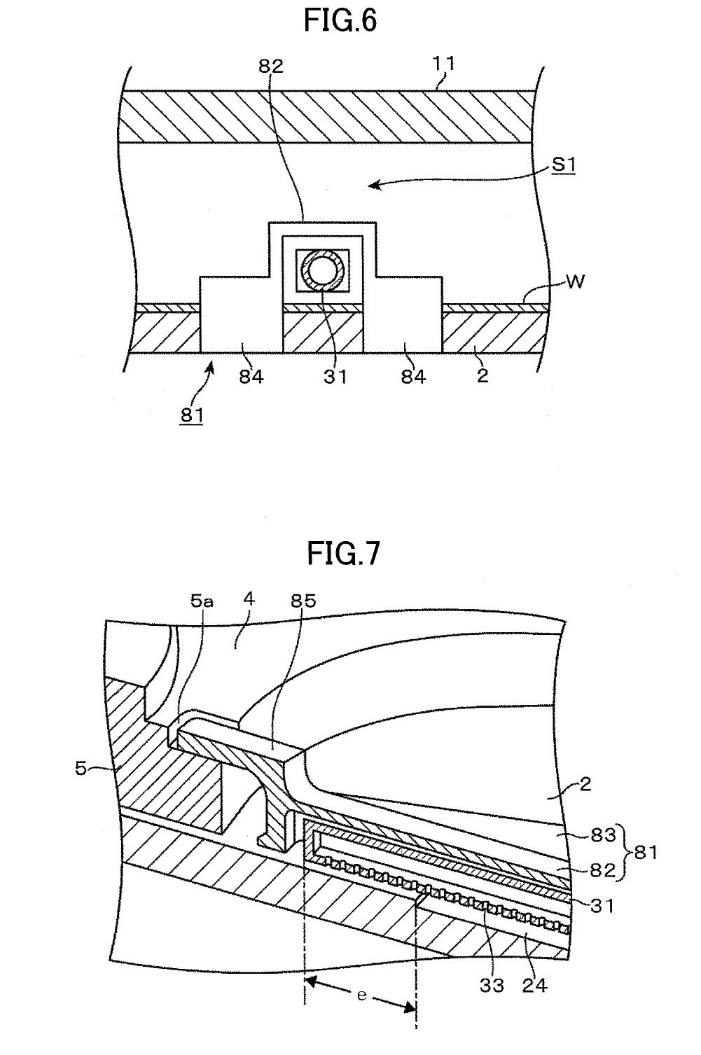

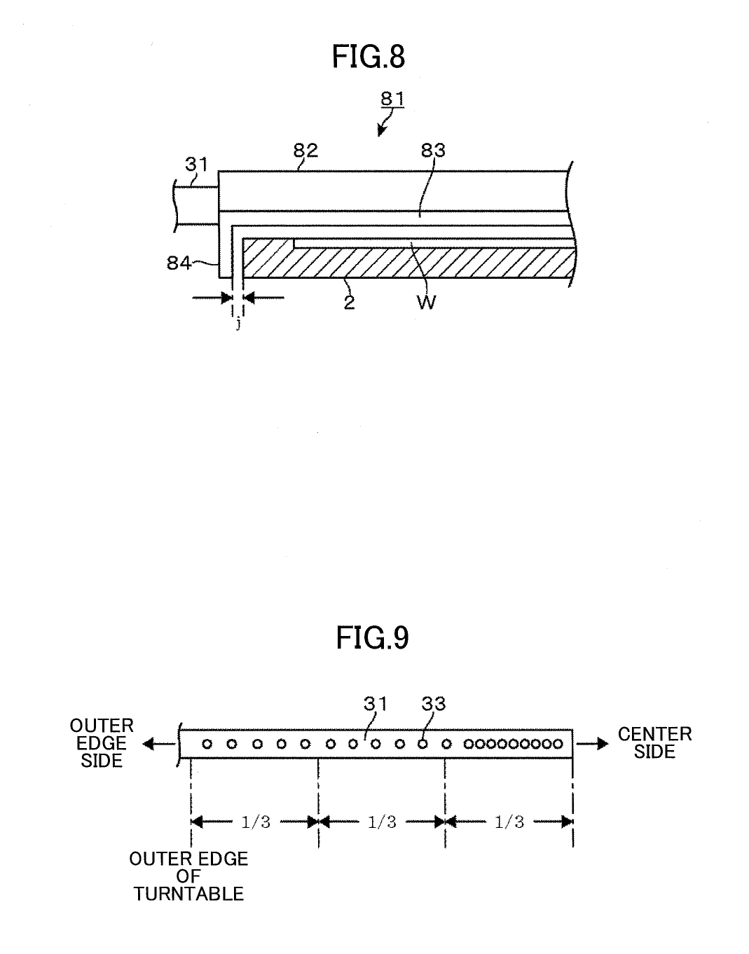

At this time, as shown in FIGS. 1, 3, 6 and 8, the edge portion on the outer circumferential side of the turntable 2 in the current plates 83 are respectively bent downward so as to face the outer edge surface of the turntable 2 at a distance therefrom and form bent sections 84. Accordingly, the bent sections 84 are respectively formed to be a sector shape when seen from a planar perspective. The position in height of the lower end of the bent section 84 is formed, for example, to be the same as the position in height of the of the lower end surface of the turntable 2. In addition, the length dimensions of the bent sections 84 in the rotational direction of the turntable 2 are formed to be the same as the length dimensions u on the outer edge side of the current plates 83 to which the bent sections 84 are respectively connected, throughout the height direction of the bent sections 84. The dimension j (see FIG. 8) between the bent sections 84 and the outer edge surface of the turntable 2 is set, for example, to be the same as the distance dimension t. In FIGS. 5 and 6, the length dimension u is simplified.

Here, reasons why the bent sections 84 are provided in the current plates 83 are described in detail. The film deposition apparatus in FIG. 1 rotates the turntable 2 so as to allow the Si containing gas and the ozone gas to be supplied onto the wafers W, as described below. Hence, the respective wafers W pass through the first process area P1, the separation area D, the second process area P2 and the separation area D in this order every time the turntable 2 rotates one revolution. Accordingly, for example, respective process conditions such as rotational speed of the turntable 2 or flow rate of the respective process gases are needed to be set so that the adsorption process of the Si containing gas and the oxidation process of components of the Si containing gas adsorbed on the wafer W are uniformly performed across the surface of the wafer W during a very short period when the wafer W passes the process areas P1, P2.

However, after experiments and simulations are performed under various process conditions, as shown in working examples described below, it is found that the process gases are needed to be supplied excessively if the adsorption process or the oxidation process are attempted to be saturated every time the turntable 2 turns one revolution; that is to say, the deposition rate is attempted to be increased as much as possible, when the nozzle cover 81 is not provided. This causes the running cost of the apparatus to increase since the process gas is very expensive. Moreover, even though the process gases are supplied excessively, obtaining favorable results regarding the film thickness uniformity throughout the surface of the wafer W is difficult.

Considering the reasons why the favorable deposition rate and film thickness uniformity cannot be achieved, it is recognized that contact probability between the wafer W and the process gas is not very high, as one of the reasons. In other words, contact period between the wafer W and the process gas cannot be taken sufficiently long in the respective process areas P1, P2 because of the following reasons: the pressure in the vacuum chamber 1 is not so high; the separation gas flows into the respective process areas P1, P2 from the upstream and downstream sides, which causes the process gases to be diluted; and the turntable 2 is rotated. Hence, to cause, for example, the Si containing gas to circulate along the wafer W on the turntable 2 and to reduce the dilution of the process gas caused by the wraparound of the separation gas, as disclosed in Patent Document 2, a configuration was considered in which the current plates 83 were provided on both sides of the first process gas nozzle 31.

As a result, as shown in the working examples, through a significant improvement of the deposition rate and the film thickness uniformity was founded compared to a case without the current plates 83, the deposition rate was still slow on the center side of the turntable 2 compared to the outer edge side, and therefore the results did not show favorable film thickness uniformity. Moreover, even though the arrangement layout of the gas discharge holes 33 such as the above-mentioned first process gas nozzle 31 and the like were considered in the configuration including the current plates 83, favorable results were not obtained.

However, when the bent sections 84 are respectively provided in the current plates 83, as shown in the working example, it was found that highly favorable results were obtained regarding the deposition rate and the film thickness uniformity. In other words, it was noted that process gas concentration under the process gas nozzle 31 is made uniform along the length direction of the first process gas nozzle 31 by providing the bent sections 84. The reasons why the process gas concentration is made uniform along the radial direction of the turntable 2 by providing the bent sections 84 are, for example, considered as follows.

As discussed above, the current plates 83 can inhibit the wraparound of the separation gas from the upstream and downstream sides in the rotational direction of the turntable 2 of the process gas area P1, but it is thought that the separation gas that circulates from the center area C toward the circumferential direction cannot be blocked from entering the process area P1 only by the current plates 83. In other words, because the process gas supplied from the process gas nozzle 31 to the process area P1 flows toward the upstream and downstream sides in the rotational direction of the turntable 2, the process gas has a function of pushing back the gas flow of the separation gas going from the respective separation areas D to the process area P1 in an opposite direction. However, as described below, a large amount of separation gas is supplied to the center area C to prevent the process gases from being mixed with each other through the center area C. Moreover, when the process area P1 is seen from the center area C, the center area C is in communication with the outer edge area of the turntable 2 through the process area P1 if the bent sections 84 are not provided (i. e., the conductance is not so high). Because of this, it can be said that the process gas supplied to the process area P1 flows to the upstream and downstream sides in the rotational direction of the turntable 2, being pushed out toward the inner wall surface of the vacuum chamber 1 by the separation gas flowing from the center area C toward the outer edge side if the current plates 83 are just provided (i.e., if the bent sections 84 are not provided). Accordingly, the concentration of the process gas is likely to be lower on the center side of the turntable 2 than on the outer edge side.

Therefore, to regulate the gas flow of the process gas likely to flow toward the outer edge side, the above-discussed bent potions 84 are provided. In other words, though the process gas is likely to be pushed out by the separation gas discharged from the center area C to the circumferential direction, when the outer edge side is seen from the process gas, the bent sections 84 are located along the circumferential direction so as to block areas between the current plates 83 and the turntable 2. Due to this, the process gas is likely to flow to the upstream and downstream sides in the rotational direction of the turntable 2 of broad spaces than to extremely narrow spaces between the bent sections 84 and the turntable 2. In other words, by disposing the bent sections 84, the process gas finds it more difficult to flow to the outer edge side than a case without disposing the bent sections 84. Hence, the process gas flows to the upstream and downstream sides along the circumferential direction of the turntable 2 so as to be along the bent sections 84. Then, the process gas reaches an area where the bent sections 84 are not disposed (i.e., an area on the upstream side of the first current plate 83a and an area on the downstream side of the second current plate 83b), and the process gas flows toward the inner wall surface of the vacuum chamber 1 with the separation gas by a suction force from the evacuation opening 61. In this way, by providing the bent sections 84, the gas flow of the process gas flowing toward the outer edge side of the turntable 2 is inhibited, and as a result, the concentration of the process gas in the radial direction of the turntable 2 (i.e., uniformity of the film thickness) becomes uniform.

In addition, by further providing the cover body 82 so as to face the tip portion of the first process gas nozzle 31, the separation gas discharged from the center area C to the circumferential directions finds it difficult to intrude into the process area P1.

Here, a description is given about a difference between the bent section 84 in the nozzle cover 81 and the bent portion 46 in the convex portion 4. The bent section 84 is to make the process gas concentration in the process area P1 uniform along the length direction of the process gas nozzle 31 as discussed above. On the other hand, the bent portion 46 is to prevent the process gases from being mixed with each other through an area between the outer edge portion of the turntable 2 and the inner wall surface of the vacuum chamber 1 as mentioned above. In other words, because the separation gas is supplied to the center area C, the bent section 84 is provided to prevent the process gas in the tip portion of the process gas nozzle 31 from being diluted by the separation gas. However, with respect to the separation area D, it can be said that the separation gas is supplied from the center area C as well as from the separation gas nozzle 41 (42). Accordingly, in the separation area D, a flow rate of the separation gas cannot run short on the center area C side when an experiment or a simulation is performed. In the meanwhile, if there is a space through which a gas can circulate between the turntable 2 on the outer edge side of the separation area D and the vacuum chamber 1, unfortunately, the process gases may be mixed with each other through the space. Therefore, the bent portion 46 is formed so as to fill the space.

The nozzle cover 81, which is configured as mentioned above, is disposed from the upper side of the first process gas nozzle 31 detachably. In other words, as shown in FIG. 7, the upper end portion on the rotational center side of the turntable 2 in the nozzle cover 81 extends upward, horizontally bends toward the center area C and forms a supporting part 85. The supporting part 85 is configured to be supported by a cutout portion 5a formed in a protrusion portion 5 described below. Moreover, as shown in FIGS. 1 through 3A, on the inner wall surface side of the vacuum chamber 1 in the nozzle cover 81, horizontal surface parts 86 that horizontally extend toward the inner wall surface are formed at two places of right and left (i.e., the upstream and downstream sides of the turntable 2), and supporting members 87 of an approximate pillar shape are respectively provided on the lower surface of the horizontal surface parts 86. The lower end surfaces of these supporting members 87 are supported by a covering member 7a described below. Here in FIGS. 6 and 8, the horizontal surface part 86 and the supporting member 87 are omitted.

Next, a description is given about the respective parts of the vacuum chamber 1 again. As shown in FIGS. 1 through 4, aside ring 100 is arranged slightly below the turntable 2 and on the outer edge side of the turntable 2. This side ring 100 is, for example, used in cleaning the film deposition apparatus, when a fluorine-system cleaning gas is used instead of respective process gasses, to protect the inner wall of the vacuum chamber 1 from the cleaning gas. In other words, it can be said that a concave air flow passage that can form an airflow (exhaust flow) in a transverse direction is formed in a ring shape along the circumferential direction between the outer edge portion of the turntable 2 and the inner wall of the vacuum chamber 1 if the side ring 100 is not provided. To prevent this, the side ring 100 is provided in the air flow passage in order to minimize exposure of the inner wall of the vacuum chamber 1 to the air flow passage.

As shown in FIG. 2, in the top surface of the side ring 100, evacuation openings 61, 62 are formed at two places so as to be away from each other in the circumferential direction. In other words, the two evacuation ports are formed below the air flow passage, and the evacuation openings 61, 62 are formed at places corresponding to the evacuation ports in the side ring 100. Among the two evacuation openings 61, 62, if one and the other are respectively called a first evacuation opening 61 and a second evacuation opening 62, the first evacuation opening 61 is formed, between the first process gas nozzle 31 and the convex portion 4 on the downstream side in the rotational direction of the turntable 2 relative to the first process gas nozzle 31, at a location closer to the separating area D side. The second evacuation opening 62 is formed, between the second process gas nozzle 32 and the convex portion 4 on the downstream side in the rotational direction of the turntable 2 relative to the second process gas nozzle 32, at a location closer to the separating area D side. The first evacuation opening 61 is to evacuate the Si-containing gas and the separation gas, and the second evacuation opening 62 is to evacuate the O₃ gas and the separation gas. As shown FIG. 1, these first evacuation opening 61 and the second evacuation opening 62 are respectively connected to, for example, vacuum pumps 64 to be vacuum evacuation mechanisms by evacuation pipes 63 including pressure controllers 65 such as butterfly valves in the middle thereof.

As shown in FIGS. 1 and 2, in the center portion under the lower surface of the ceiling plate 11, a protrusion portion 5 is provided that is formed in an approximately ring shape through in the circumferential direction from a portion on the center area C side in the convex portion 4 and whose lower surface is formed in the same height as the lower surface of the convex portion 4 (ceiling surface 44). As shown in FIG. 1, over the core portion 21 on the rotation center side of the turntable 2 relative to the protrusion portion 5, the labyrinth structure 110 is arranged to prevent the Si-containing gas and the NH₃ gas and the like from being mixed with each other in the center area C. In other words, as noted in FIG. 1, because the tip portions of the respective nozzles 31, 32, 41 and 42 are formed at a position close to the center area C, the core portion 21 that supports the center portion of the turntable 2 is formed in a position where a portion on the upper side of the turntable 2 is close to the rotation center. Accordingly, in the center area C side, for example, the process gases are likely to mix with each other compared to the outer edge side. Therefore, by forming the labyrinth structure 110, a flow passage of the gas is increased, by which mixing the process gases with each other is prevented.

More specifically, as shown in FIG. 13, the labyrinth structure 110 adopts a structure that includes a first wall portion 111 vertically extending from the turntable 2 side toward the ceiling plate 11 and a second wall portion 112 vertically extending from the ceiling plate 11 toward the turntable 2 that are respectively formed along the circumferential direction and are formed alternately in the radial direction of the turntable 2. More specifically, the second wall portion 112, the first wall portion 111 and the second wall portion 112 are arranged in this order from the protrusion portion 5 toward the center area C. In this example, the second wall portion 112 on the protrusion portion 5 forms a part of the protrusion portion 5. As an example of respective dimensions of the wall portions 111, 112, a distance j between the wall portions 111 and 112 is, for example, 1 mm, and a distance m between the wall portion 111 and the ceiling plate 11 (a gap dimension between the wall portion 112 and the core portion 21) is, for example, 1 mm.

Accordingly, in the labyrinth structure 110, for example, because a Si-containing gas discharged from the first process gas nozzle 31 and heading for the center area C is required to go over the wall portions 111, 112, the flow speed decreases as approaching the center area C and the gas becomes difficult to diffuse. Due to this, before the process gas reaches the center area C, the process gas is pushed back toward the process area P1 by the separation gas supplied to the center area C. In addition, the ozone gas heading for the center area C also finds it difficult to reach the center area C. This prevents the process gases from mixing with each other in the center area C.

As shown in FIG. 1, a heater unit 7 is provided in a space between the turntable 2 and the bottom portion 14. The wafer W on the turntable 2 can be heated to, for example, 300° C. through the turntable 2. In FIG. 1, a cover member 71a provided on the lateral side of the heater unit 7 is shown, and the cover member 71a extends to the outer circumferential side beyond the outer edge of the turntable 2 across the circumferential direction. Moreover, in FIG. 1, a covering member 7a that covers the upper side of the heater unit 7 and cover member 71a is shown. On the bottom portion 14 of the vacuum chamber 1, purge gas supplying pipes 73 to purge a space in which the heater unit 7 is arranged below the heater unit 7 are provided at plural places through the circumferential direction.

As shown in FIG. 2, the transfer opening 15 to transfer the wafer W between an external transfer arm (not shown in the drawing) and the turntable 2 is formed in the side wall of the vacuum chamber 1, and the transfer opening 15 is configured to be hermetically openable and closeable by a gate valve G. In addition, because the wafer W is transferred into or from the concave portions 24 at a position facing the transfer opening 15 with the transfer arm, lift pins for transfer to lift up the wafer W from the back side by penetrating through the concave portions 24 and the lifting mechanism (none of which are shown in the drawing) are provided at the position corresponding to the transfer position below the turntable 2.

Moreover, as shown in FIG. 1, a control part 120 constituted of a computer to control operations of the whole apparatus is provided in this film deposition apparatus, and a program to implement a film deposition process described below is stored in a memory of the control part 120. This program is constituted of instructions of step groups to cause the apparatus to implement respective operations of the apparatus, and is installed from a memory unit 121 of a storage medium such as a hard disk, a compact disc, a magnetic optical disc, a memory card and a flexible disc into the control part 120.

Next, a description is given about an action of the above-mentioned embodiment. First, the gate valve G is opened, and for example, five wafers W are loaded on the turntable 2 through the transfer opening 15 by the not shown transfer arm, while rotating the turntable 2 intermittently. Next, the gate valve G is closed; the inside of the vacuum chamber 1 is evacuated by the vacuum pump 64; and the wafer W is heated, for example, to 300° C. by the heater unit 7, while rotating the turntable 2 in a clockwise fashion.

Subsequently, the first process gas nozzle 31 discharges a Si-containing gas, and the second process gas nozzle 32 discharges an ozone gas. Furthermore, a separation gas is respectively discharged from the separation gas nozzles 41, 42 at, for example, 5000 sccm, and the separation gas is discharged from a separation gas supplying pipe 51 and the purge gas supplying pipes 72, 72 at respectively 1000 sccm, 1000 sccm and 500 sccm. Then, the pressure controller 65 adjusts a pressure in the vacuum chamber 1 at a preliminarily set processing pressure, for example, 400 to 500 Pa, and 500 Pa in this example.

The separation gas is likely to intrude into the first process area P1 from the upstream and downstream sides in the rotational direction of the turntable 2, but the process gas flows out of an area between the current plates 83 and the turntable 2. Due to this, the separation gas on the upstream side flows over the nozzle cover 81 and goes toward the evacuation opening 61. Moreover, the separation gas on the downstream side also flows toward the evacuation opening 61. By doing this, since the intrusion of the separation gas into the process area P1 from the upstream and downstream sides in the rotational direction of the turntable 2 is prevented, an area where the high concentration of process gas is stagnant is formed across the rotational direction of the turntable 2 under the nozzle cover 81.

On the other hand, the bent sections 84 prevent the separation gas discharged from the center area C to the circumferential direction from intruding into the area under the first process gas nozzle 31 as discussed above. Accordingly, the concentration of the process gas becomes uniform along the length direction of the process gas nozzle 31 in the first process area P1. Hence, on the lower side of the nozzle cover 81, an area where the concentration of the process gas is even and the dilution of the process gas is reduced (i.e., with high concentration) is broadly formed throughout the rotational direction and the radial direction of the turntable 2.

Then, when the wafer W reaches the first process area P1, the Si containing gas is adsorbed on the surface of the wafer W uniformly throughout the surface. At this time, because the area where the high concentration of process gas is distributed is widely formed under the nozzle cover 81 as discussed above, a constituent of the Si containing gas is adsorbed on the surface of the wafer W up to a degree of being saturated (i.e., up to a film thickness of saturation). Next, when the wafer W reaches the second process area P2, the constituent of the Si containing gas adsorbed on the surface of the wafer W is oxidized by the oxidation gas, and one or more molecular layers of a silicon oxide film (Si—O) of a thin film constituent are deposited, and a reaction product is deposited. In this manner, the wafer W alternately passes these process areas P1, P2 by rotation of the turntable 2, by which the reaction product is deposited and the thin film is deposited on the surface of the respective wafers W.

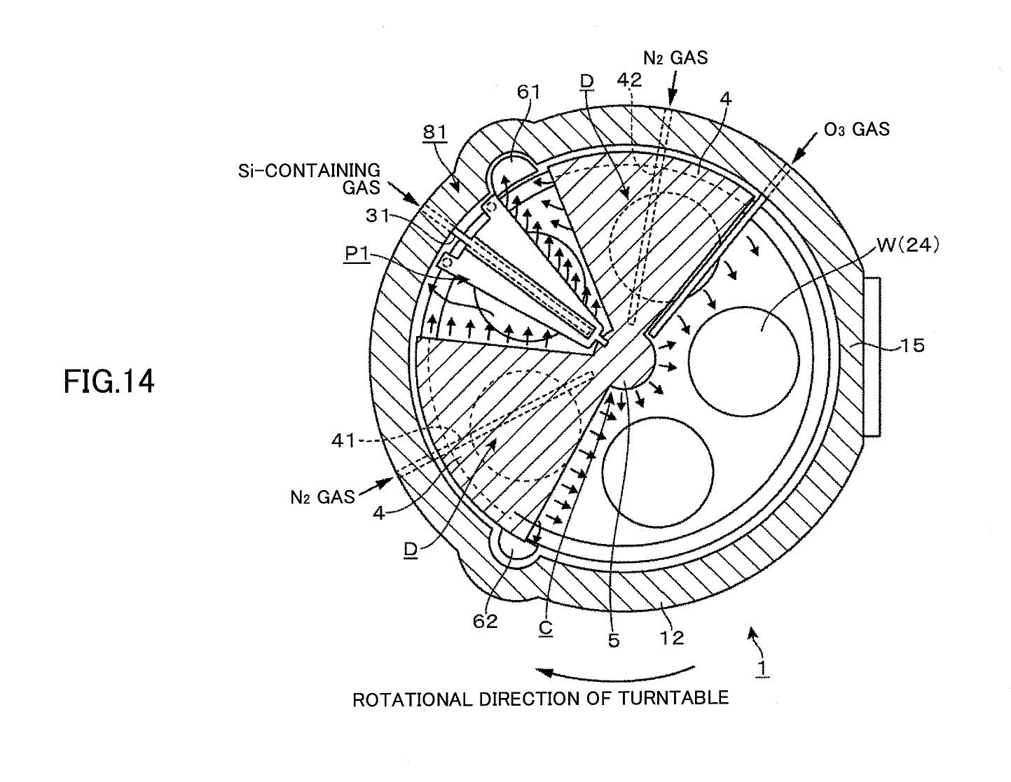

At this time, the Si containing gas and the ozone gas would likely intrude into the center area C, but the labyrinth structure 110 prevents the intrusion to the center area C. Furthermore, the separation gas is supplied to the area between the first process area P1 and the second process area P2, as shown in FIGS. 11B and 14, the Si containing gas and the ozone gas are respectively evacuated so as not to be mixed with each other. In addition, because the purge gas is supplied to the area under the turntable 2, the gas likely to be distributed to the area under the turntable 2 is pushed back toward the evacuation openings 61, 62 by the purge gas.

According to the embodiment described above, the current plates 83 are provided on the upstream and downstream sides, respectively, in the rotational direction of the turntable 2, and the bent sections 84 are formed on the inner wall surface side of the vacuum chamber 1 in the current plates 83 so as to be along the side peripheral surface of the turntable 2. This makes it possible to ensure a wide area where the process gas supplied from the first process gas nozzle 31 contacts the wafer W along the rotational direction of the turntable 2, and to make the concentration of the process gas uniform along the length direction of the first process gas nozzle 31. Accordingly, the deposition process can be performed at a favorable (fast) deposition rate, reducing an amount used of the process gas. Moreover, the film thickness of the thin film deposited on the wafer W can be made uniform throughout the surface of the wafer W, reducing the amount used of the process gas. Because of this, a film deposition apparatus that can reduce the running cost can be configured to deposit a thin film by using the ALD method.

Furthermore, as noted from the working example described below, because the length dimension u of the current plates 83 in the rotational direction of the turntable 2 is kept to a minimum dimension, to such a degree that the favorable contact time between the process gas and the wafer W can be taken, an amount used of an expensive quartz member (i.e., nozzle cover 81) can be reduced.

Furthermore, because the second current plate 83b is arranged so as not to project to the right side (downstream side) beyond the evacuation opening 61 when the evacuation opening 61 is seen from the rotation center of the turntable 2, blocking the process gas flow toward the evacuation opening 61 can be reduced.

In addition, because the number of the gas discharge holes 33 of the first process gas nozzle 31 is more on the center area C side than on the outer edge side of the turntable 2, the flow rate of the process gas on the center area C side can be compensated.

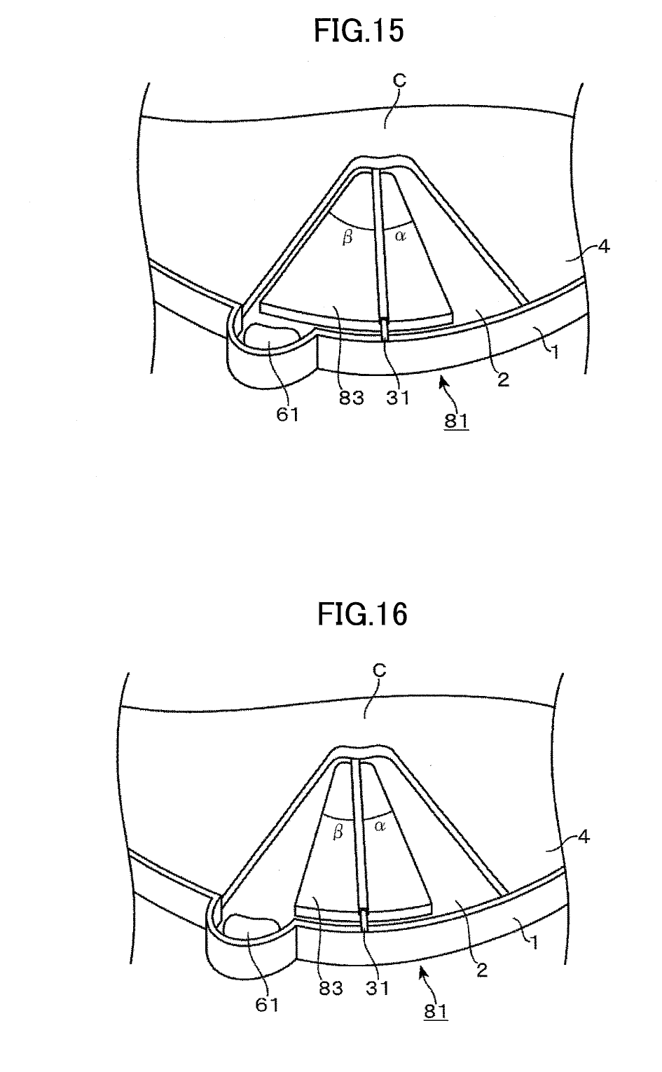

Other examples of film deposition apparatuses are detailed hereinafter. FIGS. 15 and 16 show examples that modify length dimensions u of current plates 83 in the rotational direction of the turntable 2 from the above-discussed example. More specifically, the angle α and angle β are 15 degrees and 30 degrees respectively in FIG. 15, and are 15 degrees and 15 degrees respectively in FIG. 16. Moreover, the angle θ is 0 degrees in FIG. 15, and is 15 degrees in FIG. 16.

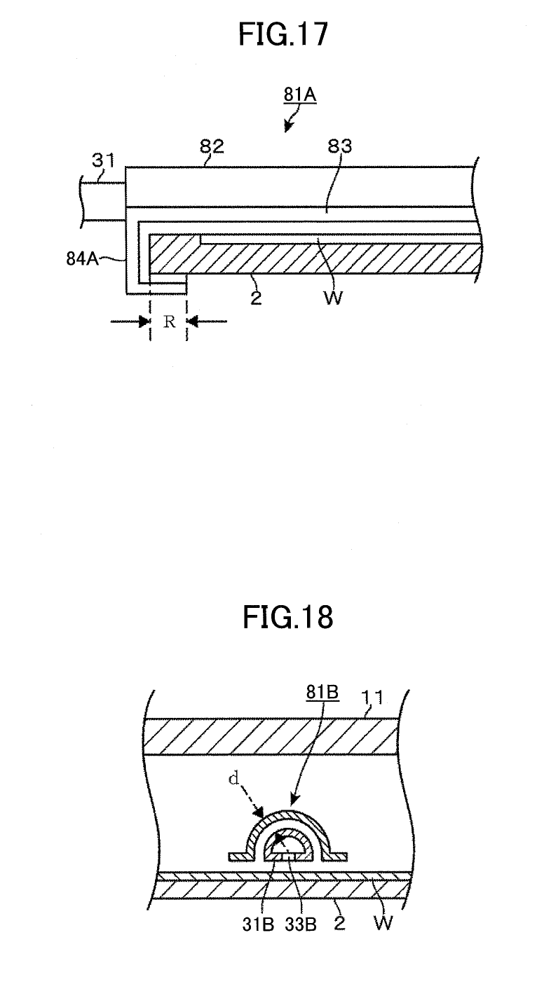

Furthermore, FIG. 17 shows an example that includes bent sections 84A that are formed so as to wrap around up to the lower surface side of the turntable 2 through the side peripheral surface of the turntable 2. A dimension R between the tip portions of the bent sections 84 and the outer circumferential portion of the turntable 2 is, for example, 20 mm. A dimension between the lower surface of the turntable 2 and the upper surface of the bent sections 84A located under the turntable 2 is set at the same degree of the above-mentioned distance dimension t.

Thus, by forming the bent sections 84A so as to wrap around the lower surface side of the turntable 2, the process gas in the process area P1 becomes difficult to circulate toward the inner wall surface side of the vacuum chamber 1. This allows the process gas concentration in the process area P1 to be further uniform along the length direction of the first process gas nozzle 31.

FIG. 18 shows an example that forms the process gas nozzle 31B under the nozzle cover 81B into a so-called arcade roof shape so that the upper surface side becomes an arc-like shape, instead of the process gas nozzle 31 formed into a rectangle when seen from the base end side (cross-section). Also in this case, the nozzle cover 81 is formed so as to be modeled on the outer surface of the process gas nozzle 31 and to make a gap dimension d between the nozzle cover 81 and the process gas nozzle 31B the same degree as the gap dimension d1, d2 discussed above.

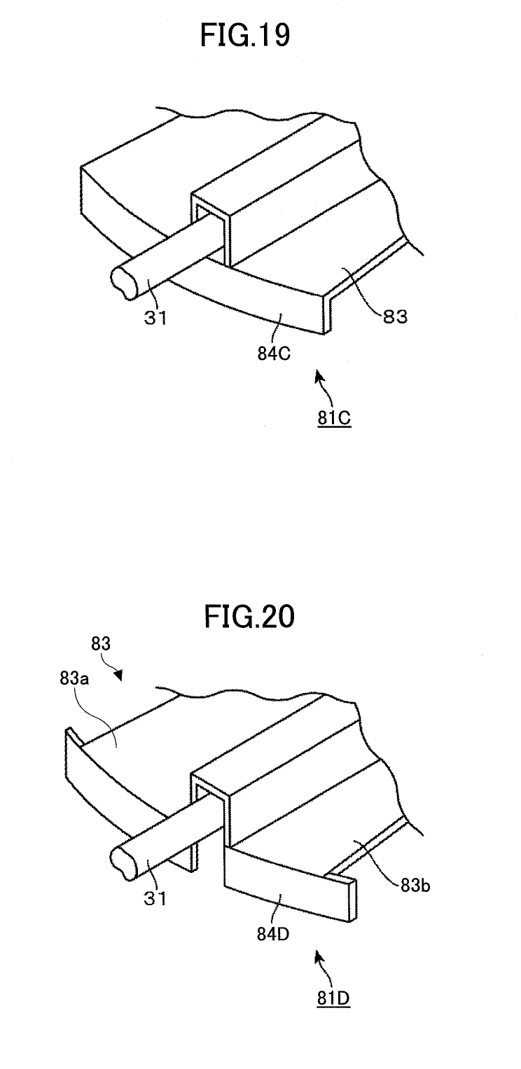

FIG. 19 shows an example that forms a bent section 84C including a portion right under the process gas nozzle 31 so as to connect the bent sections 84 on the upstream and downstream sides in the rotational direction of the turntable 2 with respect to the process gas nozzle 31 to each other. In this way, by continuously forming the bent section 84C along the length direction of the nozzle cover 81C in the rotational direction of the turntable 2, the process gas flow going from the process area P1 to the evacuation opening 61 through the area under the process gas nozzle 31 can be inhibited. In this case, the process gas nozzle 31 is inserted into the vacuum chamber 1 after the nozzle cover 81 is installed into the vacuum chamber 1.

FIG. 20 shows an example that forms bent sections 84D so that a length dimension of the bent sections 84D in the rotational direction of the turntable 2 is longer than the length dimension u of the current plates 83 to which the bent sections 84D are connected. More specifically, when the nozzle cover 81D is seen from the base end side of the process gas nozzle 31 (i.e., inner wall surface side of the vacuum chamber 1), the bent section 84D connected to the first current plate 83a is formed so as to extend from the lower side of the process gas nozzle 31 to the upstream side beyond the first current plate 83a (i.e., the second evacuation opening 62 side). Also, the bent section 84D connected to the second current plate 83b is formed so as to extend from the lower side of the process gas nozzle 31 to the downstream side beyond the second current plate 83b (i.e., the first evacuation opening 62 side).

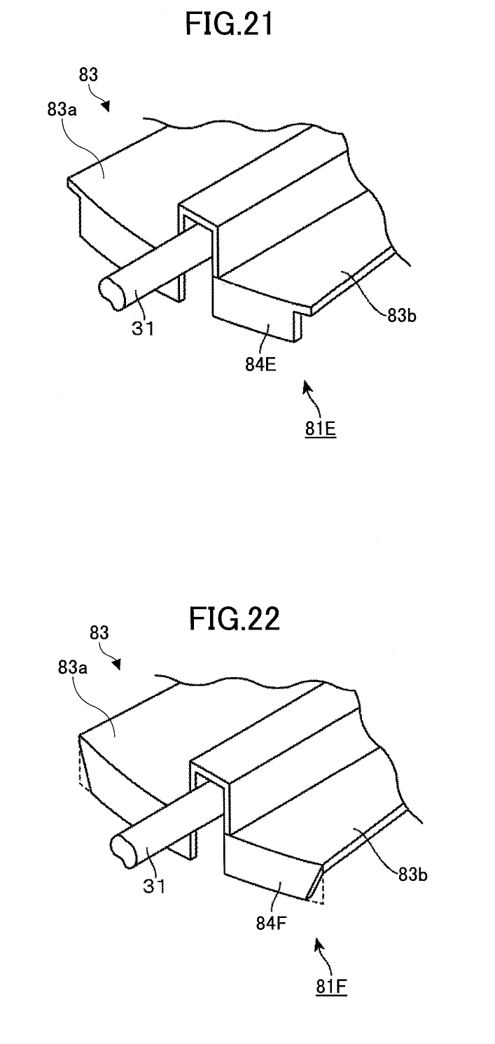

Moreover, FIG. 21 shows an example that arranges the bent section 84E connected to the first current plate 83a in a position where the end on the upstream side of the bent section 84E is closer to the process gas nozzle 31 than the end on the upstream side of the first current plate 83a. Also, the bent section 84E connected to the second current plate 83b in a position where the end on the downstream side of the bent section 84E is closer to the process gas nozzle 31 than the end on the downstream side of the second current plate 83b.

Furthermore, FIG. 22 shows an example that forms bent sections 84F so as to be formed into an approximately trapezoid when a configuration composed of two bent sections 84F is seen from the base end side of the process gas nozzle 31. More specifically, with respect to the bent section 84F connected to the first current plate 83a, the lower end portion on the upstream side is obliquely cut out. Also, with respect to the bent section 84 connected to the second current plate 83b, the lower end portion on the downstream side is obliquely cut out.

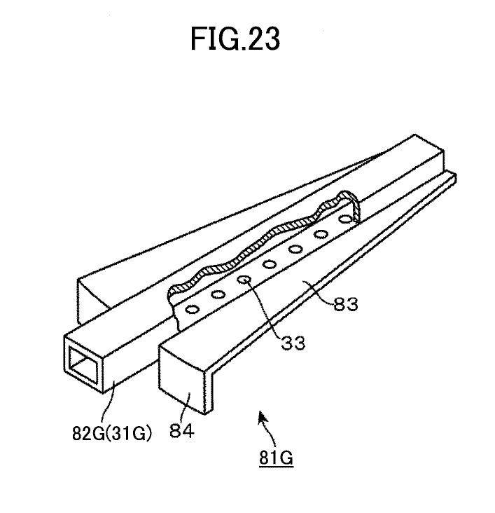

In addition, FIG. 23 shows an example that uses a cover body 82G as a process gas nozzle 31 instead of housing the process gas nozzle 31 inside the cover body 82G. In other words, the cover body 82G forms an approximately boxy body that is hermetically inserted from the inner wall side of the vacuum chamber 1, and a flow passage that allows the process gas supplied from the gas supplying source to flow is formed therein. Moreover, in the cover body 82G on the lower side of the flow passage, the gas discharge holes 33 are formed at plural places along the length direction of the cover body 82, and the current plates 83 are connected to the side surface of the cover body 82G.

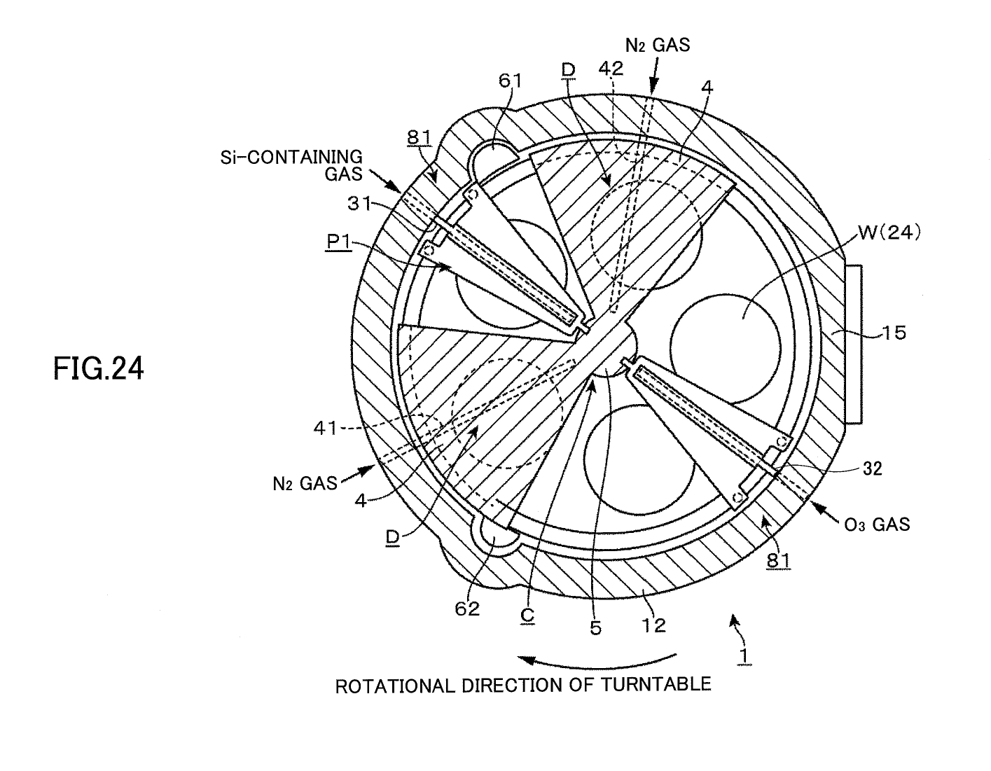

Furthermore, FIG. 24 shows an example that provides nozzle covers 81 for the second process gas nozzle 32 as well as for the first process gas nozzle 31. Thus, by further providing the nozzle cover 81 for the second gas nozzle 32, the amount used of the ozone gas as well as the Si containing gas can be reduced, and the oxidation process can be performed at a favorable process speed and with a surface uniformity. Here, FIG. 24 shows the example of the second process gas nozzle 32 provided on the downstream side of the transfer opening 15 in the rotational direction of the turntabe 12. If the nozzle cover 81 is provided for the second process gas nozzle 32, the nozzle cover 81 may not be provided for the first process gas nozzle 31.

In the above respective examples, a flow rate of the separation gas supplied to the center area C may be, for example, from 1.5 to 10 times as much as that of the Si containing gas, and may be a degree from 500 sccm to 5000 sccm in an actual flow rate.

The process gas nozzle 31 (32) may be provided so as to extend from the center area C side toward the inner wall surface side of the vacuum chamber 1 instead of inserting the process gas nozzle 31 (32) from the inner wall surface side of the vacuum char 1 toward the center area C side. In addition, the gas discharge holes 33 may be arranged in the lateral side of the process gas nozzle 31 (32), or slit-like gas discharge holes (gas dischare openings) 33 may be formed along the length direction of the process gas nozzle 31 (32). Moreover, in broadening an opening space of the gas discharge holes 33 on the center area C side larger than on the outer edge side, the number of the gas discharge holes 33 is increased in the above discussed example, but increasing an opening size of the respective gas discharge holes 33 is also possible. Furthermore, though the tip portions of the nozzles 31, 32, 41 and 42 are arranged on the center area C side beyond the edges of the wafers W on the turntable 2 in the above example, for example, the gas discharge holes 33 in the tip portions may be arranged so as to be located above the edges of the wafers W. If the gas discharge holes 33 are arranged this way, the labyrinth structure 110 in the above example may not be provided.

In addition, the current plates 83 are formed into a sector shape when seen from a planar perspective, but for example, may be formed into a rectangle.

Moreover, the bent sections 84 are, as described, to increase conductance of the gas going from the center area C side to the outer edge side by decreasing the gap between the turntable 2 and the current plates 83 when seen from the center area C side to the inner wall surface side of the vacuum chamber 1. Accordingly, the bent sections 84 only have to extend downward from the lower end portion of the current plates 83, and for example, lower end portions of the bent sections 84 may be located between the lower surface and the upper surface of the turntable 2.

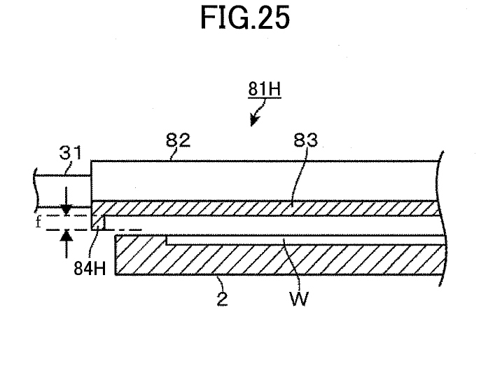

More specifically, as shown in FIG. 25, a height dimension f of the bent sections 84H from the lower end surface of the current plates 83 may be, for example, 18 mm or more. Furthermore, if the lower end portions of the bent sections 84H are located between the lower surface of the current plates 83 and the upper surface of the turntable 2 this way, the bent sections 84H may be located between the outer edge of the turntable 2 and the edges of the wafers W on the turntable 2 instead of providing the bent sections 84 on the inner wall surface side of the vacuum chamber 1 outside the outer edge of the turntable 2.

### WORKING EXAMPLE

### First Working Example

Subsequently, a description is given about experiments or simulations performed with respect to working examples according to embodiments of the present invention. First, a simulation was performed about how concentration of the process gas is like according to existence or non-existence of the nozzle cover 81 or the bent sections 84. More specifically, under a condition where a nozzle cover 81 described below is arranged, content rates of the Si containing gas contained in a gas at a location where an angle of 11 degrees is distanced from the process gas nozzle 31 in the rotational direction of the turntable 2 are respectively simulated, and the content rates are plotted along the rotational direction of the turntable 2. Here, the flow rate of the Si containing gas in respective examples is set at 0.1 slm, and in the following reference example, simulations are performed by setting the flow rate at 0.9 slm as well as at 0.1 slm. In addition, with respect to the current plates 83 in the working example and a comparative example, the angles α and β are respectively made 15 degrees and 22.5 degrees.

(Nozzle Cover)

First Working Example: Configuration with Current Plates 83 and Bent Sections 84

### Comparative Example

### Configuration with Current Plates 83 but without Bent Sections 84

### Reference Example

### Configuration without Nozzle Cover 81

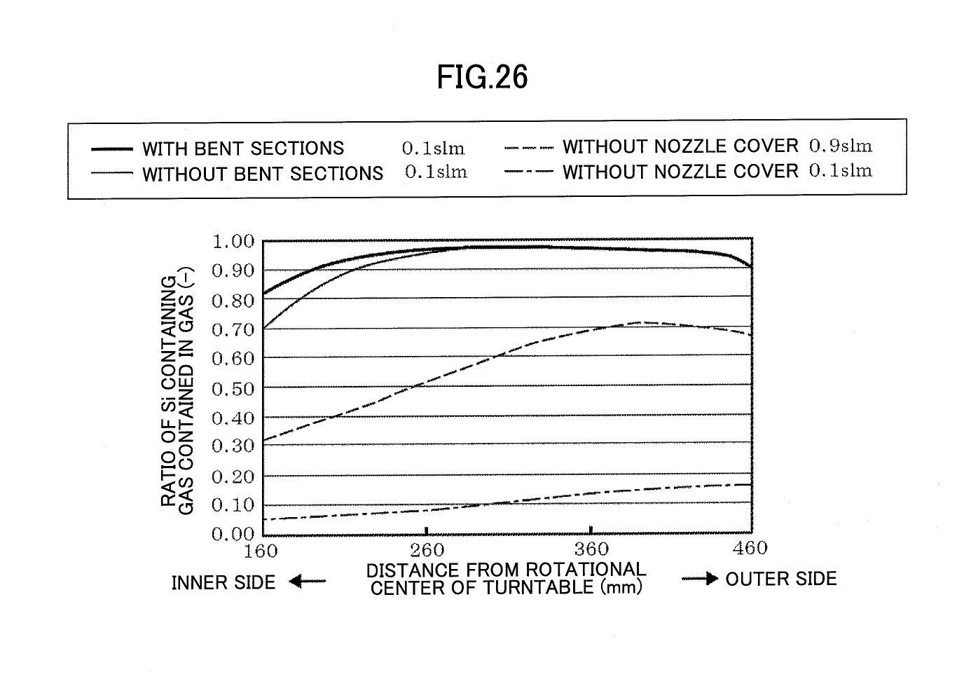

As a result, as shown in FIG. 26, by providing the bent sections 84 with current plates 83, the content rate of the Si containing gas contained in the gas becomes a highly favorable value throughout the radial direction in the turntable 2, and becomes 0.8 (80%) or more even on the center side of the turntable 2. In contrast, in the comparative example, the content rate becomes a degree of 0.7 (70%) on the center side of the turntable 2, which is lower than the first working example, and the content rate becomes a further low value in the reference example. Accordingly, the result shows that an area where the process gas concentration is high is broadly formed in the rotational direction of the turntable 2 by providing the current plates 83, and the process gas concentration on the tip side of the process gas nozzle 31 (i.e., dilution is reduced) is made high by providing the bent sections 84 with the current plates 83.

### Second Working Example

Next, as shown in the following simulation condition in Table 1, to examine values of the content rate when a length dimension of the process gas nozzle 31 or a positional relationship with the evacuation opening 61 is changed, simulations of a working example 2-1, a working example 2-2 and a working example 2-3 shown in table 1 are conducted. Here, an angle (♭+β) shown below is, as discussed with reference to FIG. 10, an angle that is formed by the straight line L2 passing the center of the process gas nozzle 31 along the length direction, and the straight line L4 passing a point in the opening edge of the evacuation opening 61 on the downstream side in the rotational direction of the turntable 2 and the rotational center of the turntable 2. Moreover, the dimension e is a distance from the tip portion of the process gas nozzle 31 to the edge of the wafer W on the turntable 2 on the rotational center side.

(Simulation Condition)

TABLE 1

| | ANGLE (θ + β) | DIMENSION e |
|---|---|---|
| WORKING EXAMPLE 2-1 | 30 | 37 |
| WORKING EXAMPLE 2-2 | 37.5 | 37 |
| WORKING EXAMPLE 2-3 | 37.5 | 17 |

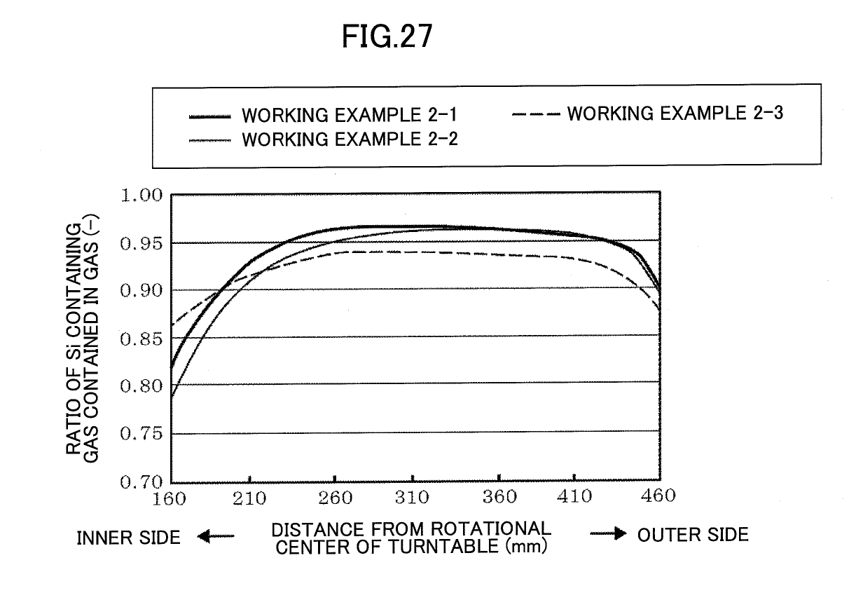

As a result, as shown in FIG. 27, by keeping apart the process gas nozzle 31 from the evacuation opening 61 toward the upstream side, and by bringing the tip portion of the process gas nozzle 31 closer to the center area C (working example 2-3, the example of FIG. 10), the content rate of the Si containing gas (film thickness uniformity of a thin film) becomes a further favorable result, and the content rate is 0.85 (85%) or more even on the center area C side.

### Third Working Example

Subsequently, as shown in the following simulation condition in Table 2, simulations shown in a working example 3-1, a working example 3-2 and a working example 3-3 of table 2 are performed about the gas content rate of the Si containing gas by changing the angles α and β of the current plates 83. A flow rate of the Si containing gas is set at 0.06 slm. Here, with respect to the example without the nozzle cover 81, a simulation is performed by setting the flow rate of the Si containing gas at 0.91 slm as the reference example.

(Simulation Condition)

TABLE 2

| | ANGLE α | ANGLE β |
|---|---|---|
| WORKING EXAMPLE 3-1 | 15 | 30 |
| WORKING EXAMPLE 3-2 | 15 | 15 |
| WORKING EXAMPLE 3-3 | 15 | 22.5 |

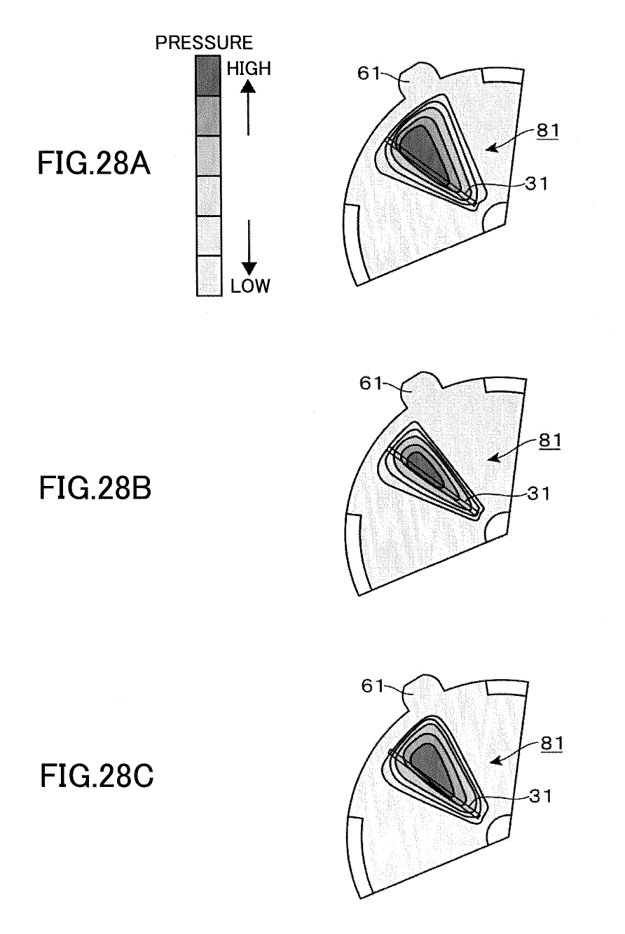

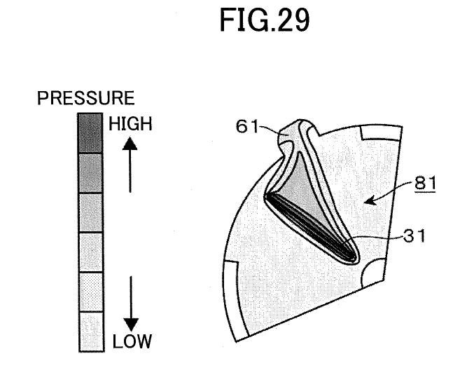

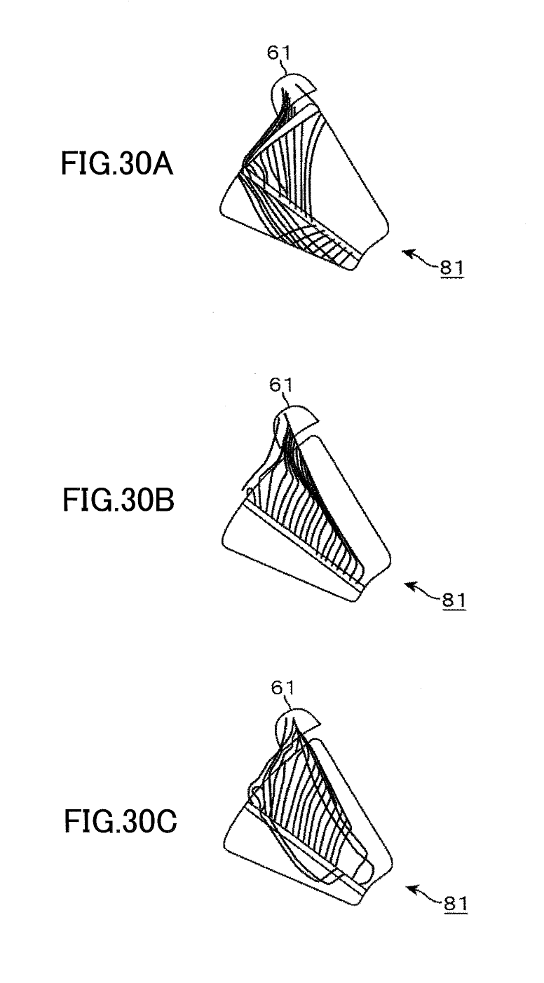

As a result, as shown in FIGS. 28A through 28C, favorable gas content rates from the tip portions to the base end side of the process nozzle 31 are obtained in any of the working examples. On the other hand, with respect to a reference example, as shown in FIG. 29, the content rate becomes extremely low except for an area under the process gas nozzle 31. At this time, as shown in FIGS. 30A through 30C, gas flows of the Si containing gas in the respective working examples are widely formed along the rotational direction of the turntable 2. Here, the reference example shown in FIG. 29 expanded a low concentration side area than that in FIG. 28 with respect to the gas content rate of the Si containing gas, and the gas content rate of the Si containing gas becomes extremely thin when expressed at the same scale as that in FIG. 28.

Here, as discussed above, considering that the nozzle cover 81 is made of expensive quartz, and therefore is favorably to be made as small as possible, and furthermore is favorably to have an area of high content rate widely formed, it can be said that the configuration of nozzle cover 81 in the working example 3-3 is the most favorable of the respective working examples 3-1 through 3-3.

### Fourth Working Example

Next, simulations similar to the third working examples are carried out by using the nozzle cover 81 of a configuration of the working example 3-3 and by setting the flow rates of the Si containing gas at 0.06 slm (working example 4-1), 0.1 slm (working example 4-2), 0.2 slm (working example 4-3) and 0.9 slm (working example 4-4) respectively.

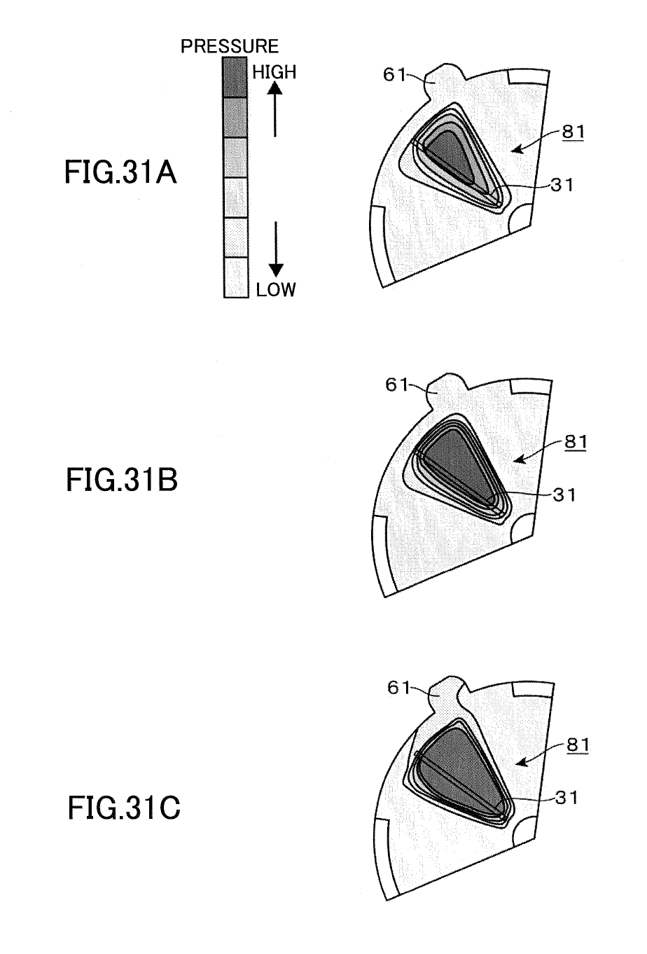

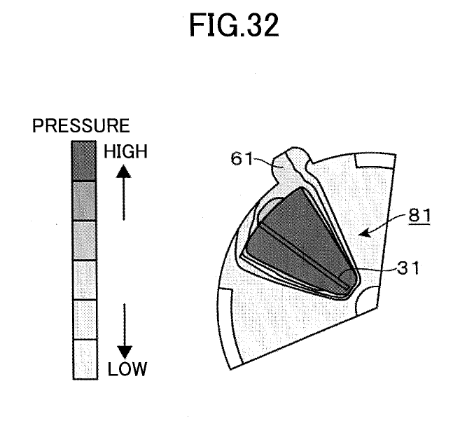

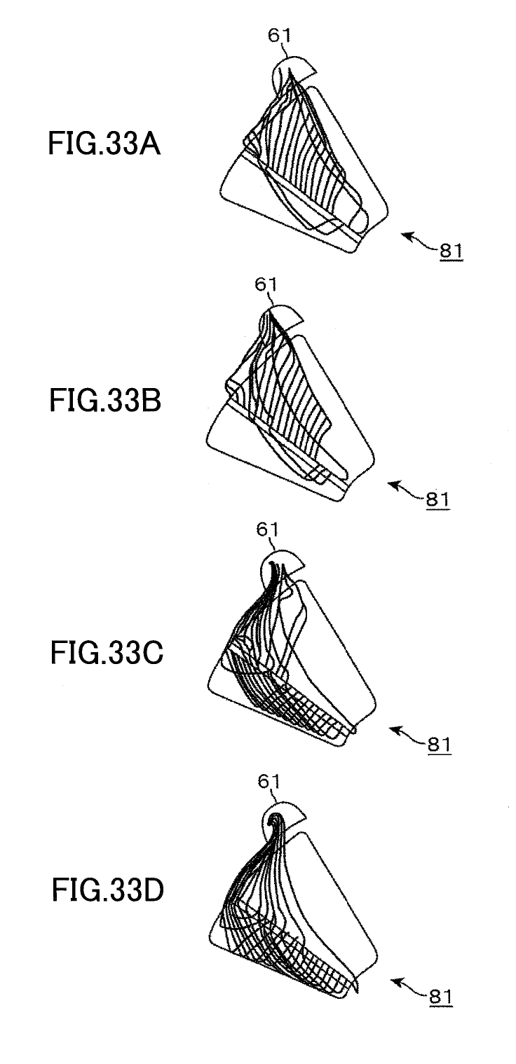

As a result, as shown in FIGS. 31A through 31C and 32, a favorable gas content rate is obtained in any of the working examples, and an area where the gas content rate of the Si containing gas is increased as the gas flow rate is increased. Moreover, as shown in FIGS. 33A through 33C, the gas flow of the Si containing gas is formed along the rotational direction of the turntable 2 in any of the working examples.

### Fifth Working Example

A description is given about simulations of a working example 5-1, a working example 5-2, a working example 5-3 and a working example 5-4 that use the configuration of the working example 3-3 about the nozzle cover 81 and set an arrangement of the gas discharge holes 33 of the process gas nozzle 31 as the following Table 3. Here, a gas discharge distribution shown in the following simulation condition in Table 3 is a distribution in which the process gas nozzle 31 inside the outer edge of the turntable 2 is divided equally into three areas in the length direction, and total opening spaces of the respective gas discharge holes 33 in these areas are expressed as a ratio from the tip portion side (center area C side) to the base end side (inner wall surface side of the vacuum chamber 1).

(Simulation Condition)

TABLE 3

| | GAS DISCHARGE |
|---|---|
| | HOLE DISTRIBUTION |
| WORKING EXAMPLE 5-1 | 1:1:1 |
| WORKING EXAMPLE 5-2 | 1.5:1:1 |
| WORKING EXAMPLE 5-3 | 2:1:1 |
| WORKING EXAMPLE 5-4 | 3:1:1 |

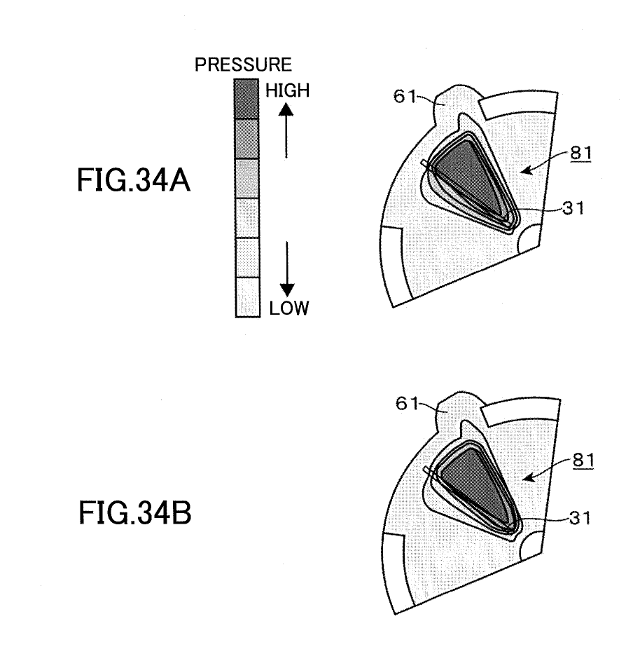

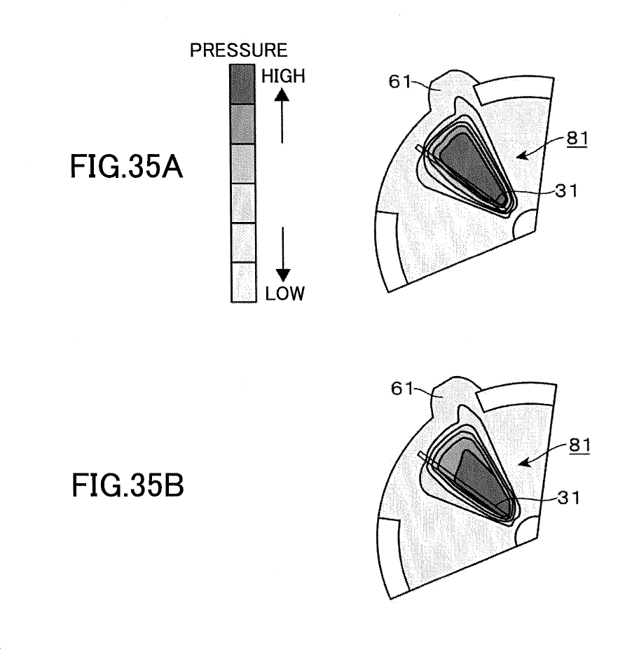

As a result, as shown in FIGS. 34A, 34B, 35A and 35B, as the opening space of the gas discharge holes 33 on the center area C side is increased, the gas content rate of the Si containing gas is increased.

### (Sixth Working Example)

Subsequently, a description is given about a result of a film deposition experiment performed by using the nozzle cover 81 of the working example 3-1 through 3-3, and by variously changing a flow rate of the Si containing gas and an opening size of the gas discharge holes 33 of the process gas nozzle 31. After depositing thin films under respective conditions, film thicknesses of these thin films are measured at plural points in the respective working examples, and a deposition rate and a uniformity of the film thickness are calculated. At this time, with respect to the nozzle cover 81, the working examples 3-1, 3-2 and 3-3 are respectively shown as “high”, “low” and “middle.” Here, because details of the experiment conditions of the sixth working example are common with the other respective examples, the description is omitted. Moreover, an example of an experiment performed without providing the nozzle cover 81 is expressed together as a reference example.

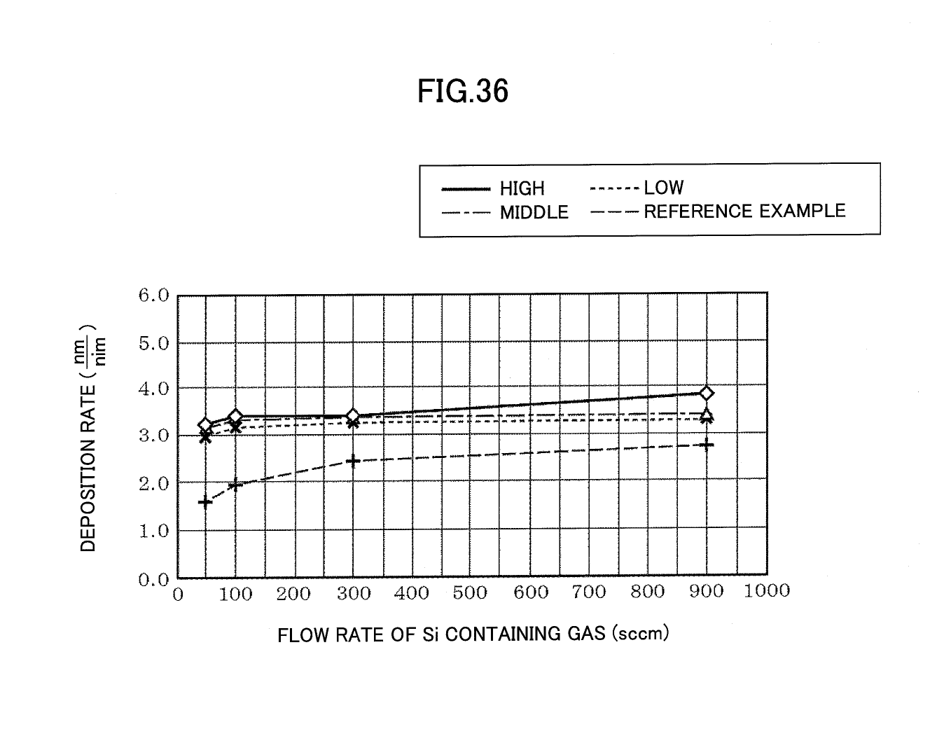

As a result, as shown in FIG. 36, when the opening size of the gas discharge holes 33 is set at 0.15 mm, favorable results are obtained in any of the working examples about the deposition rate. Then, when the flow rate of the Si containing gas is lowered up to 0.06 slm, the result is almost the same as the result of 0.9 slm. At this time, when the film thickness of the thin film is divided by the number of rotations of the turntable 2 rotated to deposit the thin film, a deposition amount per one rotation of the turntable 2 (i.e., cycle rate) is calculated. In other words, what a deposition amount is like every time the wafer W passes the process area P1 can be found. As a result of that, in the working example of the present invention, it is found that, even when the flow rate of the Si containing gas is 0.6 slm, the cycle rate is about 0.18 slm, which corresponds to an approximate saturating amount of a film thickness deposited by the ALD method.

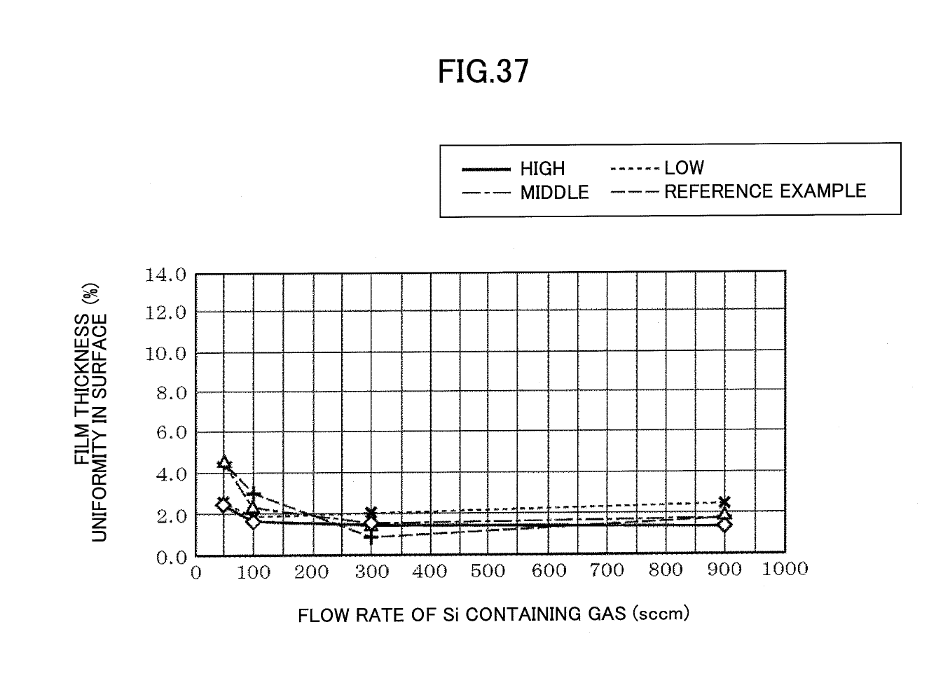

Moreover, as shown in FIG. 37, by setting the flow rate of the Si containing gas at 0.1 slim or more in any examples, favorable results of equal to or less than 2% are acquired.

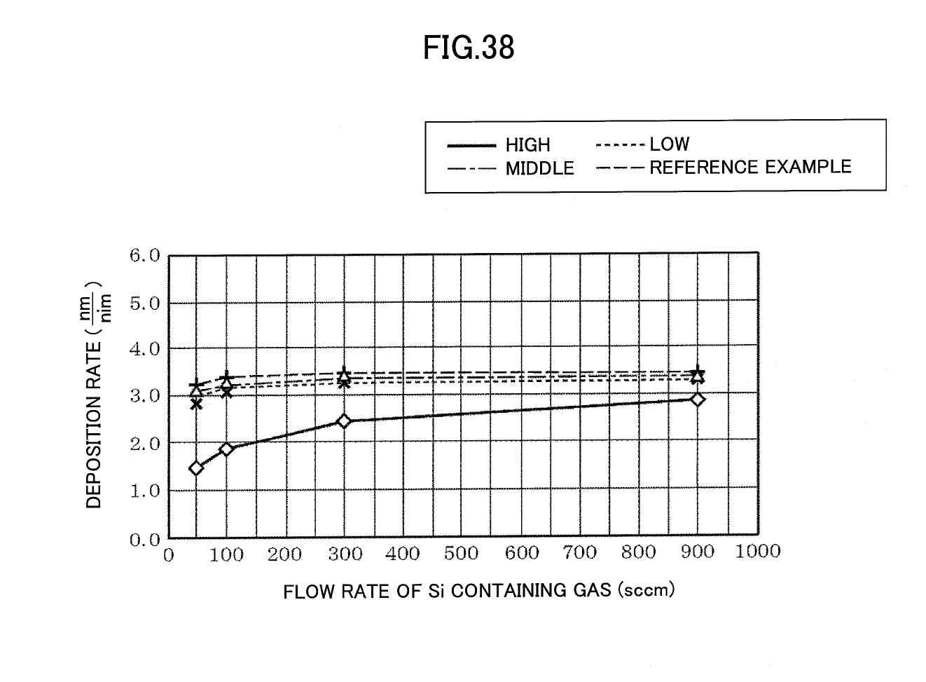

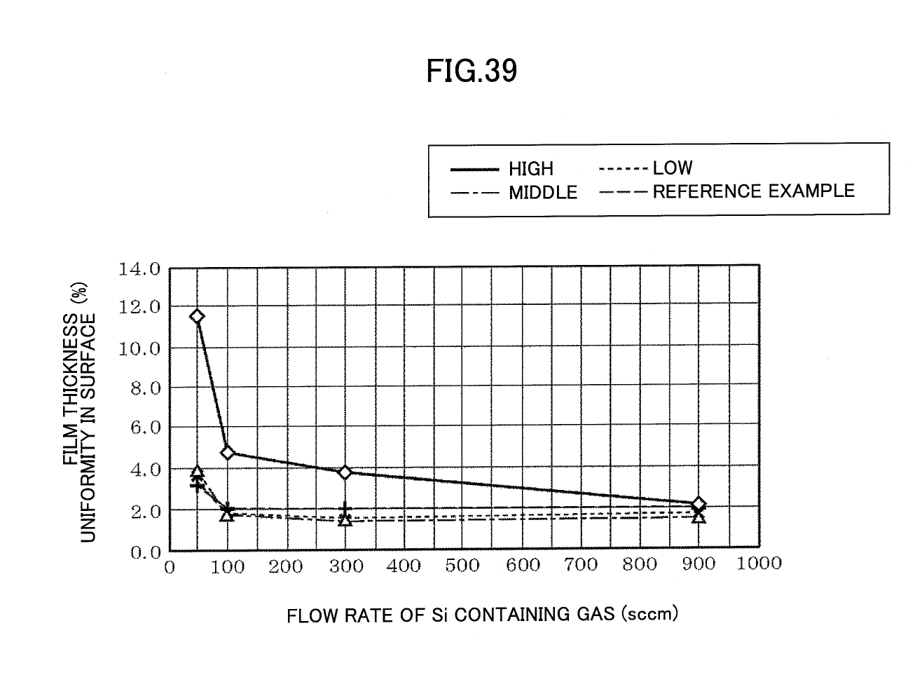

Furthermore, when the opening size of the gas discharge holes 33 is set at 0.5 mm, as shown in FIGS. 38 and 39, results similar to the above-mentioned examples are obtained.

The film deposition apparatus according to embodiments of the present invention forms at least one of process gas supplying parts for supplying a process gas into a vacuum chamber as a gas nozzle that extends from the center part to the outer edge part of a turntable, and includes current plates arranged to be along a length direction of the process gas supplying part. In addition, bent sections that extend downward along the outer edge surface of the turntable are respectively formed at a place on the outer edge side of the turntable in the current plates. Due to this, an area where the process gas supplied from the gas nozzle contacts a substrate is widely ensured along the rotational direction of the turntable. Accordingly, a deposition process can be performed at a favorable deposition rate, reducing an amount used of the process gas. Moreover, a film thickness of a thin film deposited on a surface of the substrate can be uniform throughout the surface.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A film deposition apparatus configured to deposit a thin film on a substrate by repeating a cycle of supplying plural kinds of process gases that react with each other in sequence in a vacuum chamber, the film deposition apparatus comprising:
a turntable including a substrate loading area in an upper surface to hold a substrate thereon, the turntable being configured to make the substrate loading area rotate in the vacuum chamber;
a plurality of process gas supplying parts configured to supply process gases different from each other to process areas spaced apart from each other in the circumferential direction of the turntable, at least one of the process gas supplying parts extending from a central part to a periphery and being configured to be a gas nozzle including gas discharge holes to discharge the process gas toward the turntable, the gas discharge holes being formed along a length direction of the gas nozzle;
a plurality of separation gas supplying parts formed between the process areas, the separation gas supplying parts configured to supply a separation gas for separating atmospheres of the respective process areas;
at least one evacuation opening configured to evacuate an atmosphere in the vacuum chamber;
current plates provided on upstream and downstream sides in a rotational direction of the turntable and extending along the length direction of the gas nozzle;
a circulating space above the gas nozzle and the current plates to allow the separation gas to circulate therein; and
at least one bent section bent downward from an outer edge of the current plates on the outer edge side of the turntable so as to face an outer edge surface of the turntable with a gap therefrom.

2. The film deposition apparatus as claimed in claim 1,
wherein the current plates causes the separation gas to flow above the upper surface thereof to reduce dilution of the process gas discharged from the gas nozzle, and
wherein the bent section prevents the process gas under the current plates from being exhausted to outside of the turntable.

3. The film deposition apparatus as claimed in claim 1,
wherein the bent section is bent to face a part of a lower surface as well as the outer edge surface of the turntable.

4. The film deposition apparatus as claimed in claim 1,
wherein the evacuation opening is provided between the turntable and an inner wall surface of the vacuum chamber in a radial direction of the turntable, and is located between and apart from an end of the current plates on the downstream side in the rotational direction of the turntable, and one of the other process gas supplying parts provided on the downstream side of the gas nozzle.

5. The film deposition apparatus as claimed in claim 4,
wherein the evacuation opening is configured to evacuate the process gas supplied from the gas nozzle into the vacuum chamber.

6. The film deposition apparatus as claimed in claim 1, further comprising:
a cover body provided between the gas nozzle and a ceiling surface of the vacuum chamber so as to cover the gas nozzle along the length direction and having a boxy shape whose lower surface is open so as to house the gas nozzle therein, open ends of the cover body on the upstream and downstream sides in the rotational direction of the turntable being respectively connected to the upper surfaces of the current plates.

7. The film deposition apparatus as claimed in claim 6, further comprising:
a separation gas supplying passage configured to supply the separation gas to a center area of the vacuum chamber,
wherein the open ends of the cover body on the lower end side and on the center area side are formed to have the same height as the lower surface of the current plates to prevent the separation gas supplied from the separation gas supplying passage from entering an area under the gas nozzle.

8. The film deposition apparatus as claimed in claim 1,
wherein the current plates are formed to broaden from the center side to the outer edge side when seen from a planar perspective, and
wherein the outer edge of the current plates on the outer edge side of the turntable and the bent section corresponding to the current plates have the same length in the rotational direction of the turntable.

9. The film deposition apparatus as claimed in claim 1,
wherein the gas nozzle is formed so that a distance between a lower end surface of the gas nozzle and an upper surface of the turntable is uniform in the rotational direction of the turntable so as to circulate the process gas discharged from the gas nozzle along the substrate.

10. The film deposition apparatus as claimed in claim 1,
wherein a first distance between a inner wall surface of the cover body and an outer wall surface of the gas nozzle, a second distance between the current plates and the turntable, and a third distance between a outer edge surface of the turntable and the bent sections are respectively set at a range from 0.5 to 3 mm.

11. The film deposition apparatus as claimed in claim 1,
wherein the gas discharge holes are formed to have a larger opening space on the center side than on the outer edge side of the turntable.
